(19) United States
(12) Patent Application Publication
(10) Pub. No.: US 2025/0022786 A1
(43) Pub. Date: Jan. 16, 2025

(54) METHODS AND APPARATUS FOR EDGE PROTECTED GLASS CORES

(71) Applicant: Intel Corporation, Santa Clara, CA (US)

(72) Inventors: Jeremy Ecton, Gilbert, AZ (US); Hiroki Tanaka, Gilbert, AZ (US); Haobo Chen, Chandler, AZ (US); Brandon Christian Marin, Gilbert, AZ (US); Srinivas Venkata Ramanuja Pietambaram, Chandler, AZ (US); Gang Duan, Chandler, AZ (US); Jason Gamba, Gilbert, AZ (US); Bohan Shan, Chandler, AZ (US); Robert May, Chandler, AZ (US); Benjamin Taylor Duong, Phoenix, AZ (US); Bai Nie, Chandler, AZ (US); Whitney Bryks, Tempe, AZ (US)

(73) Assignee: Intel Corporation, Santa Clara, CA (US)

(21) Appl. No.: 18/899,851

(22) Filed: Sep. 27, 2024

(51) Int. Cl. H01L 23/498; H01L 23/08

(52) U.S. Cl. CPC H01L 23/49827; H01L 23/08

(57) ABSTRACT

Methods and apparatus for edge protected glass cores are disclosed herein. An example package substrate includes a first glass layer including a first surface, a second surface opposite the first surface, and first lateral surfaces extending between the first and second surfaces, the first glass layer having a first via extending between the first surface and the second surface; and a dielectric material in contact with the first surface of the first glass layer and in contact with the first lateral surfaces of the first glass layer.

### BACKGROUND

In many integrated circuit (IC) packages, one or more semiconductor dies are mechanically and electrically coupled to an underlying package substrate. Package substrates typically include a substrate core layer (e.g., a core) between build-up layers to provide mechanical support for the IC package and/or to route signals between components coupled thereto. For example, in many electronic devices, semiconductor dies are connected to larger circuit boards such as motherboards and/or other types of printed circuit boards (PCBs) via an underlying package substrate.

### BRIEF DESCRIPTION OF THE DRAWINGS

FIG. 1 is a cross-sectional view of an example integrated circuitry (IC) package on a printed circuit board (PCB).

FIG. 2 is a cross-sectional view of an example glass core constructed in accordance with teachings disclosed herein.

FIG. 3 is a cross-sectional view of another example glass core constructed in accordance with teachings disclosed herein.

FIGS. 4A-4I illustrate various stages of manufacture of the example glass core of FIG. 2.

FIGS. 5A-5R illustrate various stages of manufacture of the example glass core of FIG. 3.

FIG. 6 is a top-down view of an example stage of manufacture of the example glass core of FIG. 3.

FIGS. 7A-7T illustrate various stages of manufacture of the example glass core of FIG. 3.

FIG. 8 is another top-down view of an example stage of manufacture of the example glass core of FIG. 3.

FIG. 9 is a flowchart representative of an example method of fabricating an example glass core disclosed herein.

FIGS. 10-12 are different portions of a flowchart representative of an example method of fabricating an example glass core disclosed herein.

FIG. 13 is a top view of a wafer including dies that may be included in an IC package constructed in accordance with teachings disclosed herein.

FIG. 14 is a cross-sectional side view of an IC device that may be included in an IC package constructed in accordance with teachings disclosed herein.

FIG. 15 is a cross-sectional side view of an IC device assembly that may include an IC package constructed in accordance with teachings disclosed herein.

FIG. 16 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

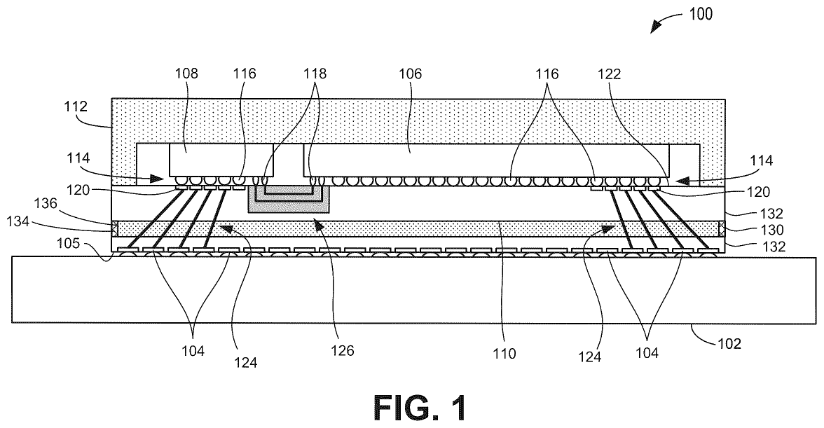

FIG. 1 illustrates an example integrated circuit (IC) package 100 constructed in accordance with teachings disclosed herein. In the illustrated example, the IC package 100 is electrically coupled to a circuit board 102 via an array of contact pads or lands 104 on a mounting surface 105 (e.g., a bottom surface) of the package. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the landing pads 104 on the bottom (external) surface 105 of the substrate 110 (e.g., a surface opposite the inner surface 122) via internal interconnects 124 within the substrate 110. As a result, there is a continuous electrical signal path between the bumps 114 of the dies 106, 108 and the landing pads 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

In FIG. 1, the package substrate 110 of the example IC package 100 includes a substrate, layer, or core 130 between two separate build-up layers or regions 132. In some examples, the thickness of the core 130 is driven by the size (e.g., footprint) of the package 100. For example, in some instances, larger packages 100 include a substrate 110 with a larger (e.g., thicker) core 130 as compared with smaller packages 100 where the core does not need to be as thick.

The build-up regions 132 are represented in FIG. 1 as masses/blocks with the internal interconnects 124 extending in straight lines through the build-up regions 132 (and the core 130). However, FIG. 1 has been simplified for the sake of clarity and purposes of explanation. In practice, the interconnects are not necessarily straight. More particularly, in some examples, the build-up regions 132 are defined by alternating layers of dielectric material and layers of conductive material (e.g., a metal such as copper). The conductive (metal) layers serve as the basis for the internal interconnects 124 represented, in a simplified form, by straight lines as shown in FIG. 1. In some examples, the metal layers are patterned to define electrical routing or conductive traces that are electrically coupled between different metal layers by conductive (e.g., metal) vias extending through intervening dielectric layers. Further, the electrical routing or traces on either side of the substrate core 130 may be electrically coupled by vias (e.g., copper plated vias, through-silicon vias (TSVs), through-glass vias (TGVs), etc.) extending through the substrate core 130.

In this example, the substrate core 130 is a glass substrate or core. In other examples, the substrate core 130 can be an organic substrate or core (e.g., an epoxy-based prepreg layer). That is, while examples disclosed herein are described as including glass cores, teachings disclosed herein can also be applied to other types of cores (e.g., epoxy-based cores). That is, in some examples, the glass core 130 is replaced with an organic and/or epoxy-based core (e.g., an epoxy-based prepreg layer with glass cloth) and/or any other suitable type of substrate core.

Glass cores offer a variety of advantages over epoxy-based cores due at least in part to the superior mechanical, physical and optical properties of glass. For example, glass is stiffer relative to epoxy-based materials and, therefore, provides for greater mechanical support or strength for the package substrate. Further, relative to epoxy-based core, glass cores provide higher through-hole density, improved mechanical and dimensional stability, ultra-low flatness, and tolerate higher temperatures. Moreover, glass core substrates enable improved signal integrity and denser routing over conventional, epoxy-based core substrates.

While glass cores offer a variety of advantages over epoxy-based cores, incorporating a glass core into a package substrate introduces challenges for which existing methods for substrate package manufacturing are inadequate. More particularly, the relatively fragile nature of glass (e.g., as compared with epoxy-based cores) increases the chances of damage to a core during fabrication of a package substrate. For example, stresses are produced in glass during patterning (e.g., during fabrication of build-up regions, interconnects layers, TGV formation, etc.), singulation, and/or other fabrication processes. These stresses produced in the glass can result in damage or defects such as (but are not limited to) a SeWaRe defect (e.g., SeWaRe separation defect), glass cracking, dielectric delamination, etc. A SeWaRe defect refers to a tear (e.g., a split, etc.) in a glass layer that occurs during or as a result of a fabrication process. For example, stress produced in a glass layer (e.g., during patterning, singulation, etc.) can strain the glass to a point where the glass layer splits (e.g., a partial split, an entire split). In some examples, the glass separates such that the glass layer splits in half.

Example methods and apparatus disclosed herein facilitate manufacture of a glass core in a manner that overcomes or at least partially mitigates these concerns. Certain examples disclosed herein enable manufacture of an edge-protected glass core in which lateral surfaces of a glass layer are provided with a protective layer. For example, the substrate core 130 of FIG. 1 includes a protective layer 134 on an edge of a glass layer 136. More specifically, the protective layer 134 is positioned on and in contact with the lateral surfaces that define the edge (e.g., perimeter) of the glass layer 136. As discussed in greater detail in relation to FIGS. 3 and 5A-8, the protective layer 134 is formed by deposition of a material (e.g., a buffer material, a dielectric material, etc.) on one or more of the lateral surfaces such that the material is in contact with the glass layer. In some examples, the protective layer 134 provides a shell (e.g., a covering, a shield, etc.) on at least a portion of the core 130 to reduce or limit instances of damage to the substrate core 130 during fabrication of the package substrate 110 (e.g., during a singulation process, fabrication of the build-up regions 132, etc.).

Methods and apparatus disclosed herein also facilitate manufacture of a multi-layer glass core having stacked glass layers (e.g., sheets, panels, etc.). In some examples, stacking multiple layers of glass for a glass core substrate reduces or limits defects in the glass core during subsequent processes (e.g., patterning of build-up regions 132, singulation, etc.). That is, multi-layer glass cores disclosed herein can withstand certain fabrication processes that are not conducive with single-layer glass cores. Certain examples disclosed herein include a dielectric material disposed between adjacent layers of glass in a multi-layer glass core to reduce a risk of damage during fabrication of a package substrate.

In some examples, multi-layer glass cores disclosed herein have an increased thickness relative to single-layer glass cores. In some examples, multi-layer glass cores disclosed herein facilitate higher aspect ratio vias relative to conventional substrate cores (e.g., single-layer glass cores, epoxy-base cores, etc.).

Example methods and apparatus are disclosed herein for advantageous through-glass vias (TGVs). In some examples, TGVs are formed using a multi-layer fill method (e.g., a bottom-up fill process, etc.) in which a TGV extending though adjacent layers of glass is plated in one process. The example multi-layer fill method disclosed herein reduces or limits stresses produced in stacked layers of glass during formation of a multi-layer TGV because a seed layer does not need to be deposited in each through-hole before a plating process. Certain example TGVs disclosed herein include different sizes (e.g., diameters, etc.) within the different layers, which can help account for alignment offset error when stacking glass layers having pre-patterned vias.

In some examples, TGVs are formed in separate fill processes such that a first via is filled in a separate plating process than a second via in an adjacent layer. In some examples, plating TGVs in separate plating processes overcomes unique challenges of high aspect ratio plating (e.g., plating voids, uniformity, long plating time, etc.).

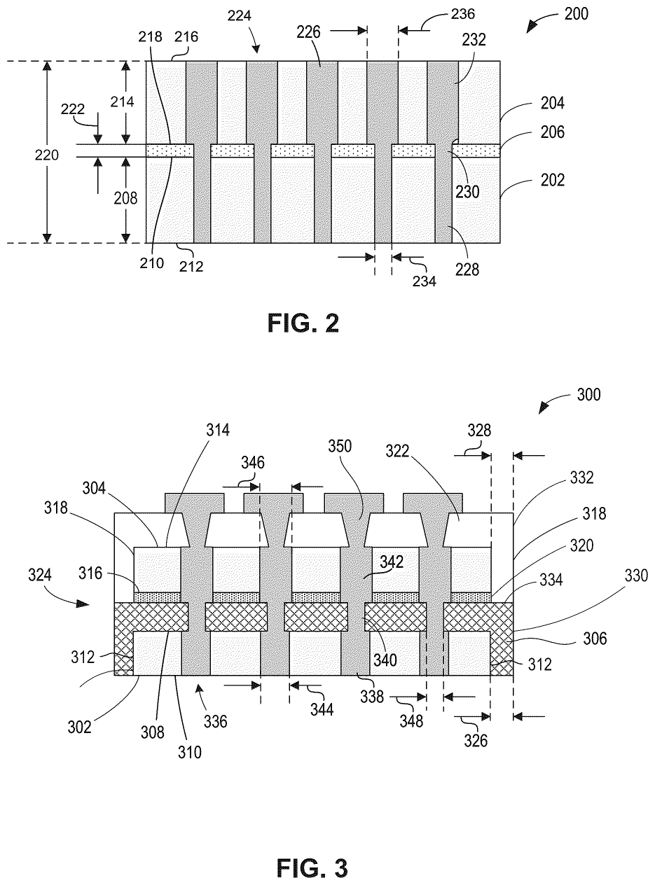

Referring again to the drawings, FIG. 2 illustrates an example glass core 200 constructed in accordance with teachings of this disclosure that can be included in an IC package substrate (e.g., the package substrate 110 of FIG. 1, etc.). The glass core 200 of FIG. 2 is a multi-layer glass core having stacked layers of glass. In this example, the glass core 200 includes an example first glass layer 202 (e.g., a glass substrate, a glass sheet, a glass panel, etc.), an example second glass layer 204 (e.g., a glass substrate, a glass sheet, a glass panel, etc.), and an example dielectric layer or material 206 positioned between the first and second glass layers 202, 204. While the example glass core 200 of FIG. 2 includes two glass layers 202, 204, in other examples, the glass core 200 may have more than two glass layers (e.g., three glass layers, four glass layers, etc.). In some such examples, adjacent layers of glass can include the dielectric material 206 disposed therebetween.

The first glass layer 202 has a first thickness 208 extending from a first surface 210 of the first glass layer 202 to a second surface 212 of the first glass layer 202 that is opposite the first surface 210 of the first glass layer 202. The second glass layer 204 has a second thickness 214 extending from a third surface 216 of the second glass layer 204 to a fourth surface 218 of the second glass layer 204 that is opposite the third surface 216 of the second glass layer 204. In this example, the fourth surface 218 of the second glass layer 204 and the first surface 210 of the first glass layer 202 are adjacent to and face towards one another. In some examples, the first thickness 208 is substantially the same as the second thickness 214. In some examples, the first thickness 208 is different than the second thickness 214.

In this example, the glass core 200 has a core thickness 220 that extends between the second surface 212 of the first glass layer 202 and the third surface 216 of the second glass layer 204. In other examples, the core thickness 220 of the glass core 200 can be different. For example, the glass core 200 can include additional glass layers and/or additional dielectric layers. In some examples, the glass core 200 can include other layers, such as a buffer layer, a seed layer, an adhesive material, etc.

In some examples, one or more of the glass layers 202, 204 has a thickness 208, 214 in a range of about 50 micrometers (μm) to about 1.4 millimeters (mm). In some examples, one or more of the glass layers 202, 204 has a thickness 208, 214 in a range of about 25 μm to about 50 μm. In some examples, one or more of the glass layers 202, 204 has a thickness 208, 214 in a range of about 25 μm to about 2 millimeters (mm). In some examples, one or more of the glass layers 202, 204 can have dimensions of about 10 mm on a side to about 250 mm on a side (e.g., 10 mm by 10 mm to 250 mm by 250 mm).

In some examples, one or more of the glass layers 202, 204 includes at least one of: aluminosilicate, borosilicate, alumino-borosilicate, silica, and/or fused silica. In some examples, one or more of the glass layers 202, 204 includes one or more additives including: aluminum oxide (Al₂O₃), boron trioxide (B₂O₃), magnesia oxide (MgO), calcium oxide (CaO), stoichiometric silicon oxide (SrO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, one or more of the glass layers 202, 204 includes silicon and oxygen. In some examples, one or more of the glass layers 202, 204 includes silicon, oxygen and/or one or more of aluminum, boron, magnesium, calcium, barium, tin, sodium, potassium, strontium, phosphorus, zirconium, lithium, titanium, and/or zinc. In some examples, one or more of the glass layers 202, 204 includes at least 23 percent silicon by weight and at least 26 percent oxygen by weight. In some examples, one or more of the glass layers 202, 204 is a layer of glass including silicon, oxygen and aluminum. In some examples, one or more of the glass layers 202, 204 includes at least 23 percent silicon by weight, at least 26 percent oxygen by weight, and at least 5 percent aluminum by weight. In some examples, one or more of the glass layers 202, 204 is an amorphous solid glass layer. In some examples, one or more of the glass layers 202, 204 is a layer of glass that does not include an organic adhesive or an organic material. In some examples, one or more of the glass layers 202, 204 is a solid layer of glass having a rectangular shape in plan view. In some examples, one or more of the glass layers 202, 204 includes at least one glass layer and does not include epoxy and does not include glass fibers (e.g., does not include an epoxy-based prepreg layer with glass cloth). In some examples, one or more of the glass layers 202, 204 corresponds to a single piece of glass that extends the full height/thickness of the core. In other examples, one or more of the glass layers 202, 204 can be silicon, a dielectric material and/or any other material(s). In some examples, one or more of the glass layers 202, 204 has a rectangular shape that is substantially coextensive, in plan view, with the layers above and/or below the core. In some examples, one or more of the glass layers 202, 204 corresponds to a rectangular prism volume with section (e.g., vias) removed and filled with other materials (e.g., metal). In some examples, one or more of the glass layers 202, 204 is an example means for strengthening a package substrate.

In some examples, a thickness 222 of the dielectric material 206 is in a range of about 1 micron to about 35 microns. However, the thickness 220 can be larger (e.g., larger than 35 microns) or smaller (e.g., less than 1 micron) in other examples. In some examples, the dielectric material 206 includes a film of a dielectric material (e.g., a dry film, a build-up film, etc.). For example, the dielectric material can include an Ajinomoto Build-up Film (ABF)®. In some such examples, the build-up film can include epoxy and a phenolic hardener (e.g., GX-T31, etc.). In some examples, the dielectric material 206 includes a glass cloth or laminate woven or dispersed therein (e.g., a dielectric build-up film having a glass cloth woven therein). For example, the dielectric material can include glass cloth and resin (e.g., epoxy, phenolic, etc.). In some such examples, the dielectric material 206 can have similar mechanical properties to the glass layers 202, 204. Further, including a glass cloth in the dielectric material 306 can increase panel stiffness and improve a rigidity of the glass core 200 to provide increased warpage control. In some examples, the dielectric material 306 includes a material having a modulus of elasticity (e.g., Young's modulus) in a range between approximately 5 gigapascals (GPa) and approximately 20 GPa. In other examples, the modulus of elasticity of the dielectric material 306 can be lower (e.g., less than 5 GPa) or higher (e.g., more than 20 GPa). In some examples, the modulus of elasticity of the dielectric material 306 is at least partially dependent on a thickness of the dielectric material 206, a manufacturing process(es) used during fabrication of the glass core 200, a substrate architecture of the glass core 200, etc. In some examples, the dielectric material 206 includes another material or film of material (e.g., a mold material, an organic material, a bond material, a polymer, etc.). Although the dielectric material 206 is represented in FIG. 2 as a single, unitary layer of material, in some examples, the dielectric material 206 may include multiple layers of the dielectric material.

While not illustrated in FIG. 2, in some examples, the dielectric material 206 can extend onto lateral surfaces (e.g., perimeter edges) of one or more of the glass layers 202, 204. For example, providing the dielectric material 206 on the lateral surfaces of the glass layers 202, 204 can provide edge protection for the glass layers 202, 204 and the glass core 200. An example edge-protected glass core is illustrated and detailed below in connection with FIGS. 3, 5A-5R, 6, 7A-7T, and 8.

The glass core 200 of FIG. 2 includes examples vias 224 (e.g., through-glass vias (TGVs)) extending therethrough to define an electrical path between different sides of the glass core 200. For example, the TGVs 224 illustrated in FIG. 2 extend from the third surface 216 of the second glass layer 204 to the second surface 212 of the first glass layer 202. While five TGVs 224 are illustrated in the example of FIG. 2, the glass core 200 can include less than five TGVs or more than five TGVs in other examples. In this example, the TGVs 224 are cylindrical (e.g., have a circular cross-sectional shape). However, the vias TGVs can have other shapes in other examples. For example, one or more of the TGVs 224 can have a different shape (e.g., hour-glass, etc.) and/or different cross-section (e.g., hexagonal, rectangular, etc.).

The TGVs 224 of FIG. 2 extend through the different layers 202, 204, 206 of the glass core 200 to define an electric path therethrough. In particular, each TGV 224 of FIG. 2 is defined by a first via or via portion 228 that extends through the first glass layer 202, a second via or via portion 230 that extends through the dielectric material 206, and a third via or via portion 232 that extends through the second glass layer 204. Different ones of the first vias 228 in the first glass layer 202 align relative to corresponding ones of the second vias 230 in the dielectric material 206, which themselves align relative to corresponding ones of the third vias 232 in the second glass layer 204. In other words, each TGV 224 includes respective vias 228, 230, 232 in the various layers 202, 204, 206 that are aligned relative to one another to form a conductive path through the glass core 200. The second vias 230 of FIG. 2 electrically couple the first glass layer 202 and the second glass layer 204.

The vias 228, 230, 232 are through-holes (e.g., cavities) having an electrically conductive material 226 therein to provide the electrical path. For example, through-holes for the vias 228, 230, 232 can be formed (e.g., etched, drilled or laser cut, etc.) and subsequently filled (e.g., plated) with the conductive material 226 to form conductive pillars (e.g., TGVs 224) that provide the electrical path between different sides of the glass core 200. The electrically conductive material 226 can include, for example, copper, gold, aluminum and/or any other electrically conductive material(s).

In other words, the first vias 228 are first through-holes extending through the first glass layer 202 that are filled (e.g., plated) with the conductive material 226 to generate an electrical path therethrough. The second vias 230 are second through-holes extending through the dielectric material 206 that are filled (e.g., plated) with the conductive material 226 to generate an electrical path therethrough. Moreover, the third vias 232 are third through-holes extending through the second glass layer 204 that are filled (e.g., plated) with the conductive material 226 to generate an electrical path therethrough. Different ones of the first through-holes in the first glass layer 202 align relative to corresponding ones of the second through-holes in the dielectric material 206, which themselves align relative to corresponding ones of the third through-holes in the second glass layer 204.

In the illustrated example of FIG. 2, the first vias 228 of the first glass layer 202 have a first width or first diameter 234 and the third vias 232 in the second glass layer 204 have a second width or second diameter 236. In this example, the first diameter 234 is different than the second diameter 236. More specifically, the first diameter 234 of the first vias 228 is smaller than the second diameter 236 of the third vias 232 (e.g., to help account for alignment offset errors when stacking the layers 202, 204). In other examples, the first diameter 234 can be larger than the second diameter 236. In yet other examples, the first diameter 234 can be substantially similar to the second diameter 236. As used herein, a first dimension (e.g., the first diameter 234) of a via (e.g., the first via 228) is substantially similar to a second dimension (e.g., the second diameter 236) of a second via (e.g., the third via 234) when the first dimension is within 20 μm of the second dimension. In some examples, the glass core 200 includes additional layer(s) having a third diameter that is the same as the first diameter 234, the same as the second diameter 236, or different than the first and second diameters 234, 236.

In some examples, the TGVs 224 have an aspect ratio that is relatively high compared to traditional single-layer glass cores. As used herein, an aspect ratio of a TGV refers to a thickness of core through which the TGV extends to a diameter of the TGV in the core. In some examples, the core thickness 220 of the glass core 200 is larger relative to single-layer glass cores due to the stacked layers 202, 204, 206 of the multi-layer glass core 200. The through-holes for the TGVs 224 are generated in the separate layers 202, 204, 206, enabling the multi-layer glass core 200 to be fabricated to have higher aspect-ratio TGVs 224 relative to traditional cores. In some examples, the TGVs 224 have an aspect ratio that is between approximately 12:1 and approximately 15:1. However, the aspect ratio of the TGVs 224 can be higher (e.g., 16:1, 20:1, etc.) or smaller (e.g., 10:1, 9:1, etc.) in other examples.

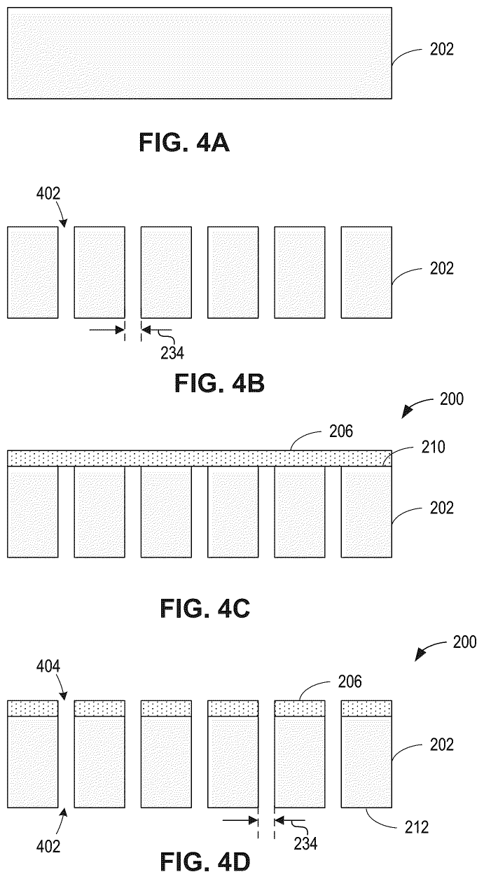

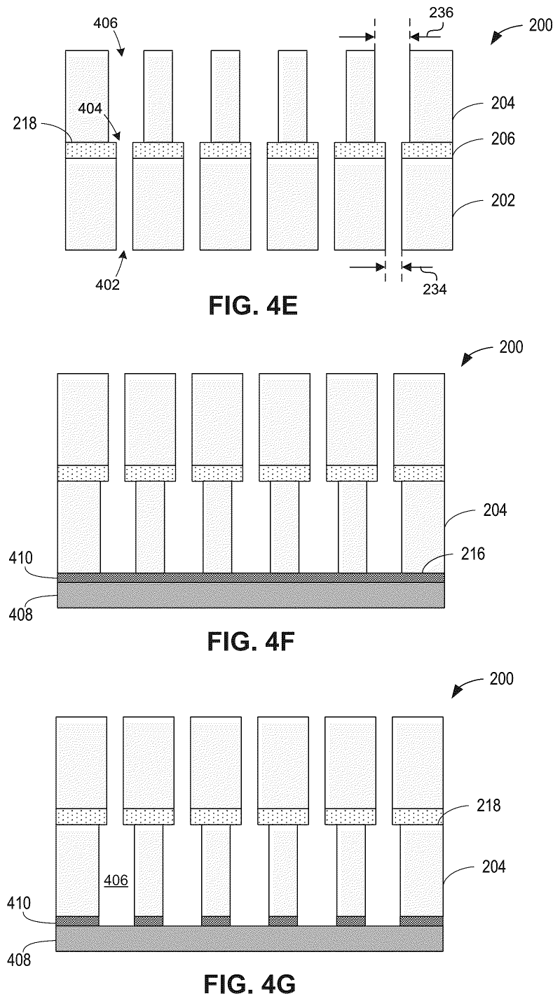

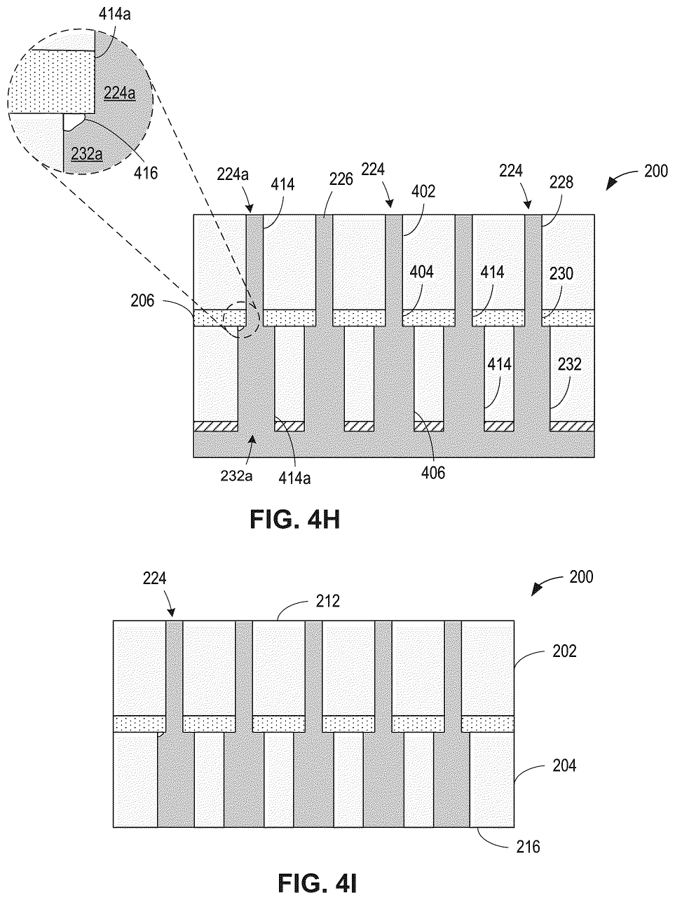

In some examples, the TGVs 224 are formed using the example multi-layer fill method disclosed herein. For example, the through-holes for the vias 228, 230, 232 can be generated and, after the through-holes in the different layers 202, 204, 206 are formed, each TGV 224 can be generated by plating respective ones of the vias 228, 230, 232 together. As discussed in greater detail in relation to FIGS. 4A-4I, using a multi-layer fill method can result in less stress in the TGVs 224 during fabrication thereof.

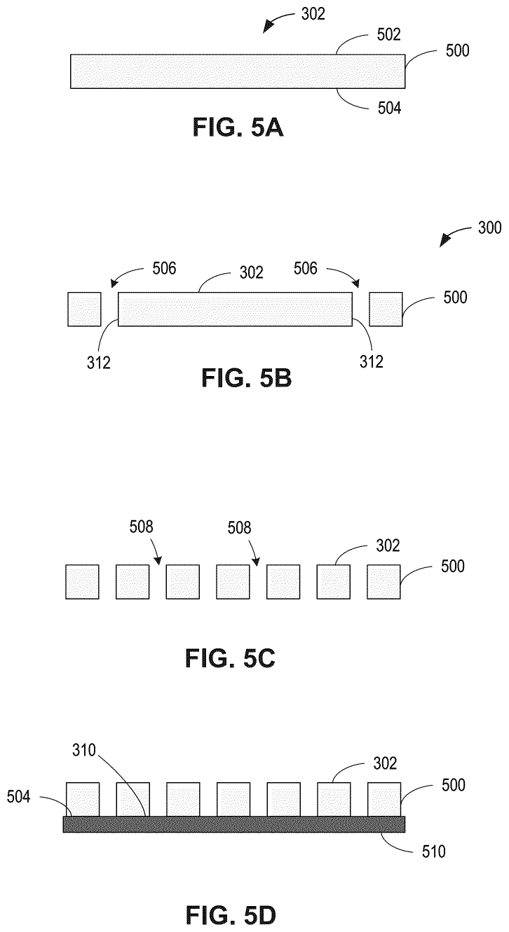

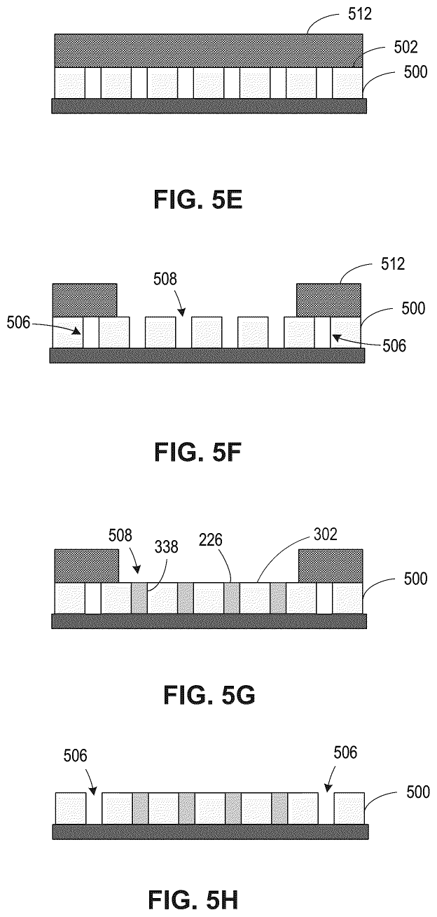

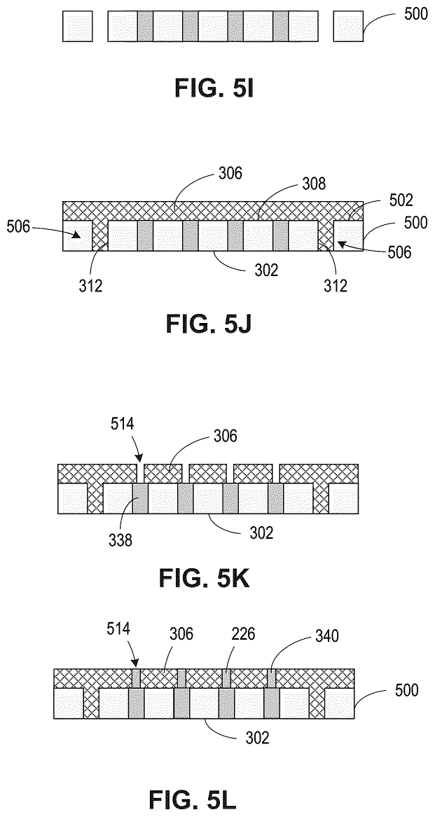

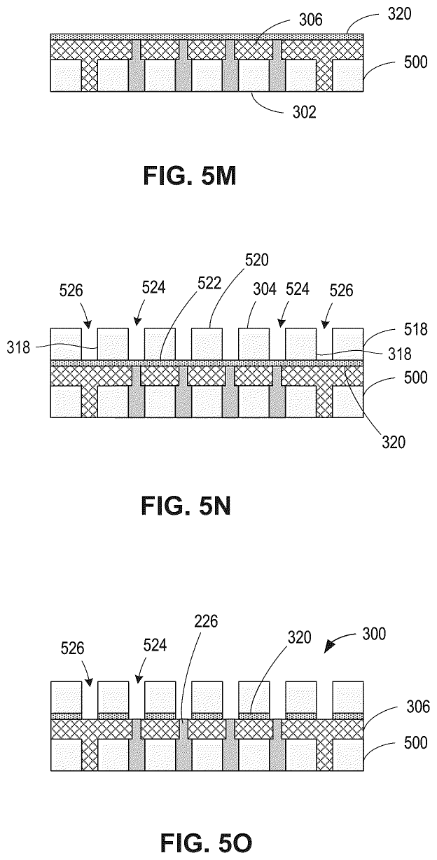

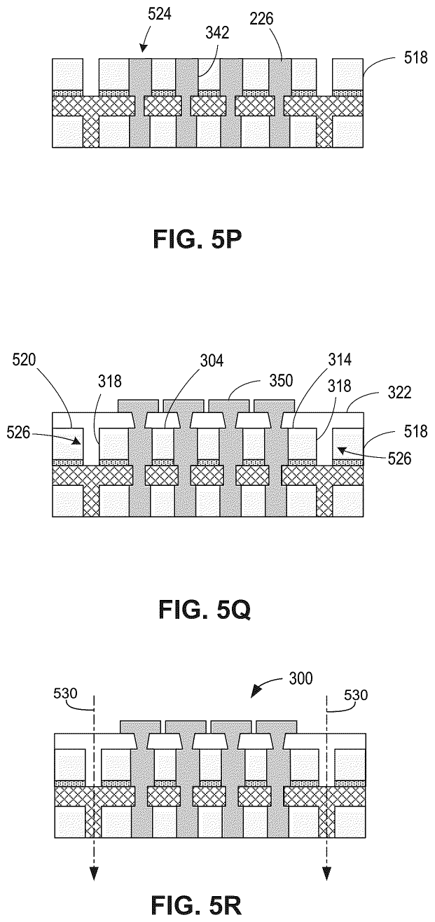

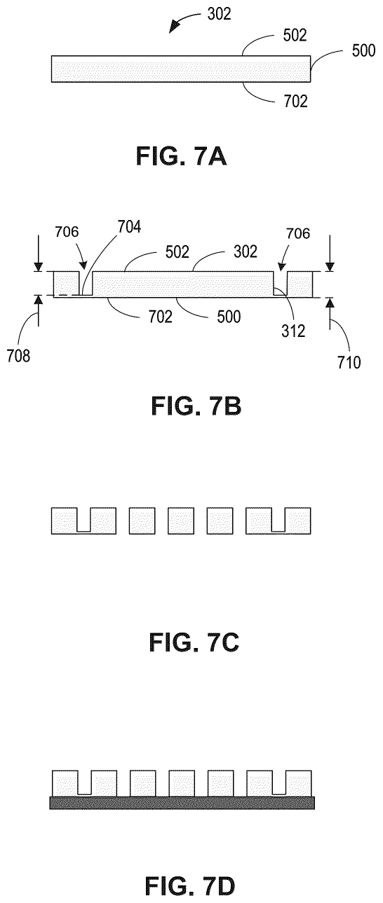

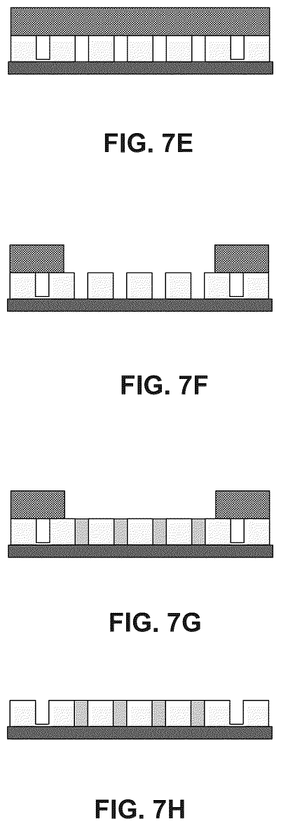

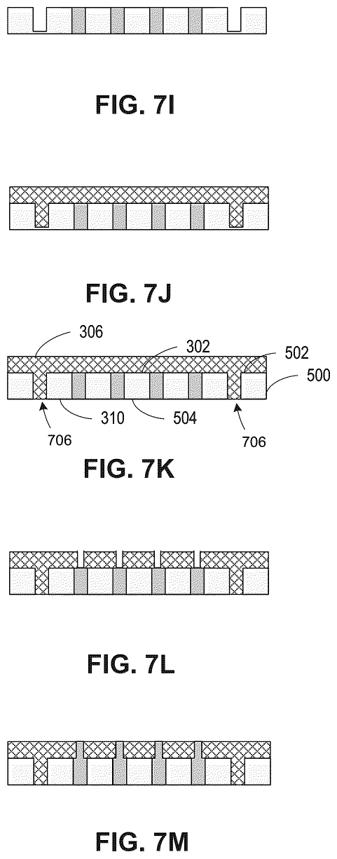

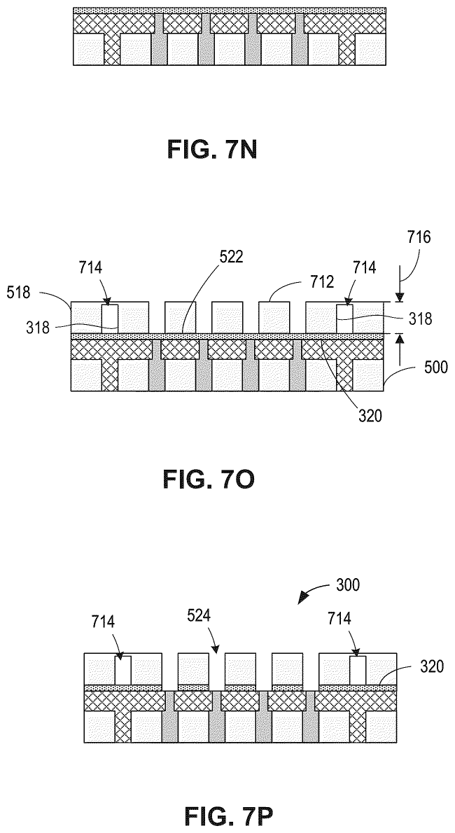

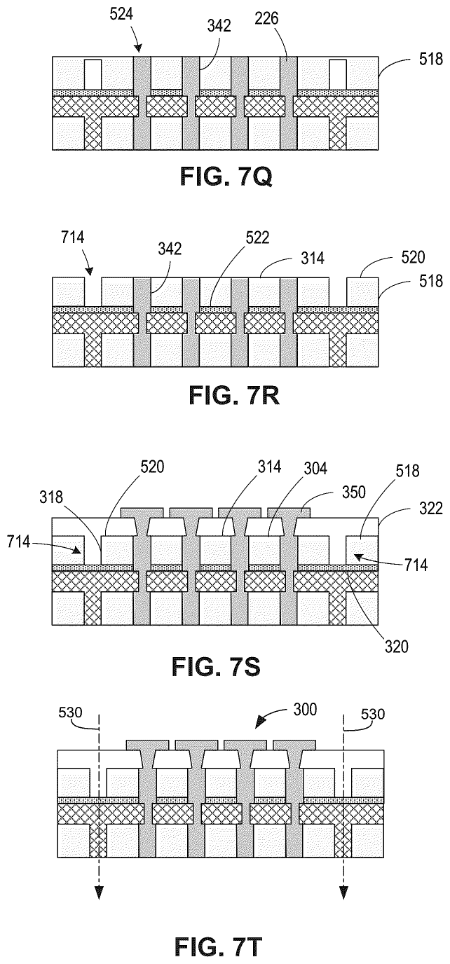

In other examples, different ones of the vias 228, 230, 232 are plated in separate processes (discussed in further detail below in relation to FIGS. 3, 5A-5R, and 7A-7T). For example, the first vias 228 in the first glass layer 202 can be plated in a first plating process, the second vias 230 in the dielectric material 206 can be plated in a second plating process, and the vias 232 in the second glass layer 204 can be plated in a third plating process. As discussed in greater detail in relation to FIGS. 5A-5R and 7A-7T, plating the vias 228, 230, 232 for the TGVs 224 in separate processes can help overcome unique challenges of high aspect ratio plating (e.g., plating voids, uniformity, long plating time, etc.)

FIG. 3 illustrates another example glass core 300 constructed in accordance with teachings disclosed herein that can be included an IC package substrate (e.g., the package substrate 110 of FIG. 1). Many of components of the glass core 300 of FIG. 3 are substantially similar or identical to the components described above in connection with the glass core 200 of FIG. 2. As such, those components will not be described in detail again below. Instead, the interested reader is referred to the above corresponding descriptions for a complete written description of the structure and operation of such components.

Similar to the glass core 200 of FIG. 2, the glass core 300 of FIG. 3 is a multi-layer glass core having stacked layers of glass, including an example first glass layer 302 (e.g., the glass layer 202 of FIG. 2), an example second glass layer 304 (e.g., the glass layer 204 of FIG. 2), and an example dielectric layer or material 306 (e.g., the dielectric material 206 of FIG. 2) disposed between the first and second glass layers 302, 304. However, unlike the glass core 200 of FIG. 2, the glass core 300 of FIG. 3 is an edge-protected glass core. More specifically, as will now be discussed in greater detail, edges of the glass layers 302, 304 are at least partially covered by a protective material (e.g., a dielectric material, a buffer material, etc.).

The first glass layer 302 of FIG. 3 includes a first surface 308, a second surface 310 opposite the first surface 308, and first lateral surfaces 312 (e.g., edge surfaces, perimeter edges, etc.) that extend between the first and second surfaces 308, 310. The first lateral surfaces 312 define a first edge (e.g. perimeter) of the first glass layer 302. In this example, the first lateral surfaces 312 defining the first edge extend in a direction that is substantially perpendicular to the first surface 308 of the first glass layer 302. As used herein, “substantially perpendicular” means exactly perpendicular or within +/−5 degrees of exactly perpendicular.

The second glass layer 304 of FIG. 3 includes a third surface 314, a fourth surface 316 opposite the third surface 314, and second lateral surfaces 318 (e.g., edge surfaces, perimeter edges, etc.) that extend between the third and fourth surfaces 314, 316. The second lateral surfaces 318 define a second edge (e.g., perimeter) of the second glass layer 304. In this example, the second lateral surfaces 318 defining the second edge extend in a direction that is substantially perpendicular to the third surface 314 of the second glass layer 304. In the illustrated example of FIG. 3, the fourth surface 316 of the second glass layer 304 and the first surface 308 of the first glass layer 302 are adjacent and face towards one another.

In this example, an adhesive material 320 (e.g., a bond material, etc.) is positioned between the first glass layer 302 and the second glass layer 304. Particularly, the adhesive material 320 is disposed between the second glass layer 304 and the dielectric material 306. The adhesive material 320 is structured to bond or couple the second glass layer 304 to the first glass layer 302 having the dielectric material 306. In some examples, the adhesive material 320 is omitted. In some examples, the adhesive material 320 extends fully along the dielectric material 306.

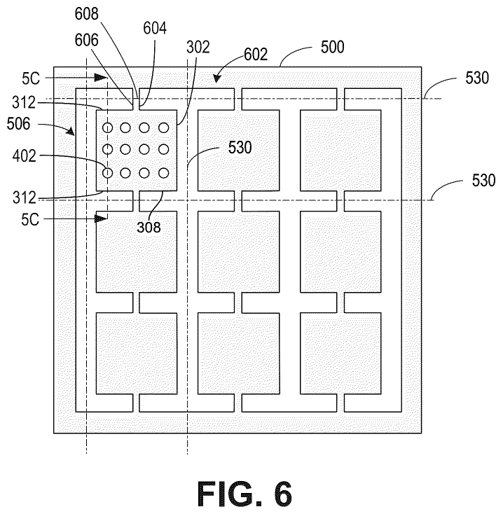

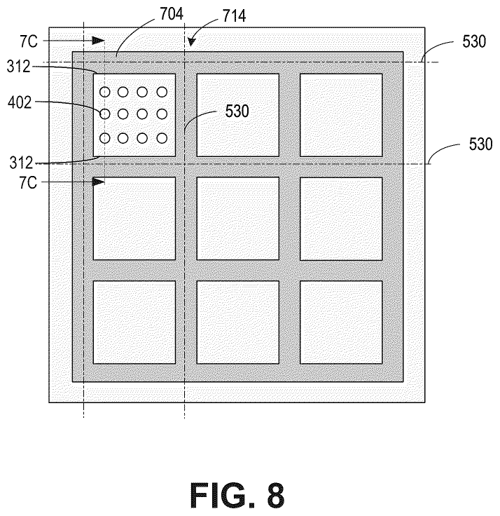

Like the glass core of FIG. 2, the dielectric material 306 of FIG. 3 is disposed on (e.g., in contact with) the first surface 308 of the first glass layer 302. However, unlike the glass core 200 of FIG. 2, the dielectric material 306 of FIG. 3 is disposed on (e.g., in contact with) the first lateral surfaces 312 (e.g., the first edge) of the first glass layer 302. In some examples, the dielectric material 306 is disposed along a full distance of the surfaces 308, 312. In some such examples, the dielectric material 306 substantially encloses or covers the first edge of the first glass layer 304. Some such examples are discussed in greater detail in relation to FIGS. 7A-7T and 8. In other examples, the dielectric material 306 may be disposed along a portion of one or more of the surfaces 308, 312. For example, the dielectric material 306 may be disposed along only a portion of one or more of the first lateral surfaces 312. In some such examples, as discussed in greater detail in relation to FIGS. 5A-5R and 6, a glass protrusion (e.g., extension, overhang, protuberance, etc.) can extend from one or more of the first lateral surfaces 312 of the first glass layer 302.

In the illustrated example of FIG. 3, a buffer material 322 is disposed on surfaces of the second glass layer 304. More specifically, the buffer material 322 of FIG. 3 is disposed on (e.g., in contact with) the third surface 314 of the second glass layer 304 and disposed on (e.g., in contact with) the second lateral surfaces 318 of the second glass layer 304. In some examples, the buffer material 322 includes a dielectric material or layer (e.g., the dielectric material 306 and/or another dielectric material disclosed herein). For example, the buffer material 322 can be another layer(s) of the dielectric material 306. In some examples, the buffer material 322 includes a build-up film (e.g., ABF® GY18, ABF® GY20, etc.). In some examples, the buffer material 322 includes a photo-imageable dielectric material. In some examples, the buffer material 322 includes the same material as the dielectric material 306. In other examples, the buffer material 322 is a different material as the dielectric material 306.

Similar to the dielectric material 306, in some examples, the buffer material 322 is disposed along a full distance of the surfaces 314, 318 such that the buffer material 322 substantially encloses the second lateral surfaces 318 (e.g., the second edge) of the second glass layer 304 (e.g., as discussed in relation to FIGS. 7A-7T and 8). In other examples, the buffer material 322 may be disposed along a portion of one or more of the surfaces 314, 318 (e.g., along only a portion of one or more of the second lateral surfaces 318). In some such examples, as discussed in greater detail in relation to FIGS. 5A-5R and 6, another glass protrusion can extend from one or more of the second lateral surfaces 318 of the second glass layer 304.

The lateral surfaces 312, 318 of the layers 302, 304 of the glass core 300 are at least partially covered (e.g., enclosed, etc.) by a protective layer 324 (e.g., a shell, protective covering, etc.). In this example, the protective layer 324 includes the dielectric material 306 and the buffer material 322. In particular, the first lateral surfaces 312 (e.g., the first edge) of FIG. 3 are at least partially overlaid by the dielectric material 306 and the second lateral surfaces 318 (e.g., the second edge) of FIG. 3 are at least partially overlaid by the buffer material 322. In other examples, the protective layer 324 can include additional or alternative materials.

As previously mentioned, stresses produced during fabrication of the package substrate 110 (FIG. 1) often cause damage and/or defects in glass during fabrication of glass core package substrates. However, the protective layer 324 of the edge-protected glass core disclosed herein protects or shields the glass layers 302, 304 during fabrication to reduce or eliminate damages to the glass core 300. For example, the protective layer 324 is disposed at least partially along a singulation saw street of the glass core 300. As discussed in greater detail in relation to FIGS. 5A-5R, 6, 7A-7O and 8, during singulation of the glass core 300, the protective layer 324 provides a barrier between a cutting process and the glass layers 302, 304. Further, the protective layer 324 can aid in protecting the glass layers 302, 304 during patterning processes of subsequent layers (e.g., other glass layers, build-up layers, interconnect layers, etc.).

As illustrated in the example of FIG. 3, a first edge thickness 326 of the dielectric material 306 disposed along the first lateral surfaces 312 is substantially similar to a second edge thickness 328 of the buffer material 322 disposed along the second lateral surfaces 318. In other examples, the first edge thickness 326 can be different than the second edge thickness 328. In this example, the first edge thickness 326 of the dielectric material 306 is different than a first surface thickness of the dielectric material 306 disposed along the first surface 308 of the first glass layer 302. In other examples, the first edge thickness 326 can be the same of the first surface thickness. In this example, the second edge thickness 328 of the buffer material 322 is different than a second surface thickness of the buffer material 322 disposed along the third surface 314 of the second glass layer 304. In other examples, the second edge thickness 328 can be the same of the second surface thickness.

In the illustrated in FIG. 3, first outer lateral surfaces 330 of the dielectric material 306 are substantially flush with corresponding second outer lateral surfaces 332 of the buffer material 322. In some examples, the flush nature of these surfaces 330, 332 is achieved by the cut of a saw during a singulation process. The first and second outer lateral surfaces 330, 332 at least partially define an edge of the glass core 300.

Further, a portion of the buffer material 322 is in contact with a portion of the dielectric material 306 at least partially along a perimeter of the glass core to define an interface 334. The interface 334 can be substantially parallel relative to the first surface 308 of the first glass layer 302. As used herein, “substantially parallel” means exactly parallel or within +/−5 degrees of exactly parallel. In some examples, the interface 334 is interrupted by one or more glass protrusion(s) extending from one or more of the lateral surfaces 312, 318 of the glass layers 302, 304. In some examples, the interface 334 is omitted. For example, in some instances, the adhesive material 320 is positioned between the buffer material 322 and the dielectric material 306 such that the buffer material 322 and the dielectric material 306 are not in contact.

The glass core 300 of FIG. 3 includes examples TGVs 336 (e.g., TGVs 224 of FIG. 2) extending therethrough to define an electrical path between different sides of the glass core 300. While four TGVs 336 are illustrated in the example of FIG. 3, the glass core 300 can include less than four TGVs or more than four TGVs in other examples. The TGVs 336 of FIG. 3 are similar to the TGVs 224 of FIG. 2. For example, each TGV 336 of FIG. 3 includes a first via or via portion 338 (e.g., the first via 228 of FIG. 2) extending through the first glass layer 302, a second via or via portion 340 (e.g., the second via 230 of FIG. 2) extending the dielectric material 306, and a third via or via portion 342 (e.g., the third via 232 of FIG. 2) extending through the second glass layer 304. The vias 338, 340, 342 are through-holes generated in the layers 302, 304, 306 and subsequently filled (e.g., plated) with conductive material (e.g., the conductive material 226 of FIG. 2). Different ones of the first vias 338 in the first glass layer 302 align relative to corresponding ones of the second vias 340 in the dielectric material 306, which themselves align relative to corresponding ones of the third vias 342 in the second glass layer 304 to form conductive pillars (e.g., TGVs 336) that provide the electrical path between different sides of the glass core 300.

In the illustrated example of FIG. 3, the first vias 338 have a first width or diameter 344 that is substantially similar to a second width or diameter 346 of the third vias 342. The second vias 340 of FIG. 3 have a third width or diameter 348 that is different than the diameters 344, 346 of the first and third vias 338, 342. In particular, the third diameter 348 of the second vias 340 in the dielectric material 306 is smaller than the diameters 344, 346 of the first and third vias 338, 342 in the glass layer 302, 304. In other examples, one or more of the second vias 340 can have a diameter that is substantially similar to or larger than one or more of the diameters 344, 346 of the glass layers 302, 304.

In the illustrated example of FIG. 3, example interconnects 350 extend through the buffer material 322. The interconnects 350 of FIG. 3 are shown as bumps that protrude beyond an outer surface of the buffer material 322. However, the interconnects 350 may be any other type of electrical connection in addition to or instead of the bumps shown (e.g., balls, pins, pads, wire bonding, etc.). Further, in some examples, the interconnects 350 are flush with and/or recessed relative to the outer surface of the buffer material 322. The interconnects 350 of the buffer material 322 align with respective ones of the TGVs 336 to define electrical paths through the glass core 300.

The foregoing examples of the glass cores 200, 300 of FIGS. 2 and 3 teach or suggest different features. Although each example glass cores 200, 300 disclosed above has certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features.

FIGS. 4A-4I illustrate various stages of manufacture of an example multi-layer glass core (e.g., the glass core 200 of FIG. 2, the glass core 300 of FIG. 3, etc.) in accordance with teachings disclosed herein. In particular, FIGS. 4A-4I illustrate an example method to manufacture a stacked glass core disclosed herein. For the sake of simplicity, the various stages of manufacture of FIGS. 4A-4I are illustrated and described in relation to the glass core 200 of FIG. 2. However, aspects described herein can be applied to manufacture other stacked glass cores disclosed herein.

For purposes of explanation, the various stages of manufacture illustrated in FIGS. 4A-4I have been simplified to produce one glass core. However, aspects described in relation to FIGS. 4A-4I can be applied at the panel-level or wafer-level such that the glass core 200 can be singulated (e.g., separated) from other glass cores manufactured therewith.

Turning in detail to the drawings, FIGS. 4A-4I are cross-sectional illustrations of the example glass core 200 of FIG. 2 at various manufacturing stages. FIG. 4A illustrates the first glass layer 202 of FIG. 2. In some examples, the first glass layer 202 is part of a glass panel or wafer such that the first glass layer 202 is one of multiple first glass layers for different glass cores that are to be cut out of the glass panel or wafer.

FIG. 4B illustrates the first glass layer 202 after example first through-holes 402 have been formed in the first glass layer 202. In this example, the first through-holes 402 correspond to the first vias 228 of the glass core 200 of FIG. 2. The first through-holes 402 have a diameter that defines the first diameter 234 of the first vias 228 (FIG. 2). That is, the first through-holes 402 have the first diameter 234.

FIG. 4C illustrates the glass core 200 after the dielectric material 206 is deposited onto the first glass layer 202. In particular, the dielectric material 206 is deposited onto the first surface 210 of the first glass layer 202.

FIG. 4D illustrates the glass core 200 after second through-holes 404 have been formed in the dielectric material 206. In this example, the second through-holes 404 correspond to the second vias 230 of the glass core 200 of FIG. 2. As illustrated in FIG. 4D, the second through-holes 404 align relative to the first through-holes 402 of the first glass layer 202. In some examples, the second through-holes 404 are formed using a self-aligning dry etch process. For example, the first glass layer 202 can implement or otherwise act as a mask, and a dry-etch process can be applied from the second surface 212 of the first glass layer 202. Thus, the second through-holes 404 of the dielectric material 206 have a diameter that is substantially the same as the first diameter 234. It is understood, however, that the second through-holes 404 can be formed using any suitable process.

FIG. 4E illustrates the glass core 200 after the first glass layer 202 having the dielectric material 206 has been coupled (e.g., bonded, attached, etc.) with the second glass layer 204. In some examples, example third through-holes 406 are provided in the second glass layer 204 (e.g., pre-patterned through-holes) before the second glass layer 204 is coupled with the first glass layer 202. That is, the second glass layer 204 having the third through-holes 406 can be coupled to the first glass layer 202 having the dielectric material 206. In this example, the fourth surface 218 of the second glass layer 204 is bonded with the dielectric material 206 of the first glass layer 202.

The second glass layer 204 can be aligned relative to the first glass layer 202 such that the third through-holes 406 substantially align relative to the first and second through-holes 402, 404. The third through-holes 406 have a diameter that defines the second diameter 236 of the third vias 232 (FIG. 2). That is, the third through-holes 406 have the second diameter 236.

As illustrated in FIG. 4E, the first diameter 234 of the first through-holes 402 is different than the second diameter 236 of the third through-holes 406. This difference between the first diameter 234 and the second diameter 236 can help account for alignment offset error during the alignment process. For example, when a pick-and-place tool positions the second glass layer 204 relative to the first glass layer 202, the second glass layer 204 may be at least partially offset relative to the first glass layer 202 (e.g., due to real-world tolerances and machine errors). However, because the second diameter 236 is larger than the first diameter 234, the third through-holes 406 will still be at least partially aligned with the first and second through-holes 402, 404. As such, when the through-holes 402, 404, 406 are plated to generate the vias 228, 230, 232, the resulting TGVs 224 will form to provide an electrical path through the glass core 200.

In some examples, a pick-and-place tool can generate alignment offset in a range of about 5 microns to about 10 microns. In some such examples, a difference between the second diameter 236 and the first diameter 234 can be between approximately 10 microns and approximately 20 microns larger than the first diameter 234. However, the alignment offset can be larger (e.g., more than 10 microns) or smaller (e.g., less than 5 microns, zero, etc.) in other examples. Moreover, a difference between the second diameter 236 and the first diameter 234 can be larger (e.g., more than 20 microns) or smaller (e.g., less than 10 microns) in other examples.

FIG. 4F illustrates the glass core 200 after a conductive layer 408 (e.g., a conductive substrate, etc.) has been attached to the third surface 216 of the second glass layer 204. In this example, the conductive layer 408 is coupled to the second glass layer 204 using a bond material 410 (e.g., an adhesive material or film). The conductive layer 408 is a temporary carrier that aids in the plating of the TGVs 224 (FIG. 2). More specifically, the conductive layer 408 implements or acts as an electrical path used to plate the vias 228, 230, 232 of the TGVs 224. The conductive layer 408 is formed of a conductive material, such as (but not limited to) copper, aluminum, etc. For example, the conductive layer 408 can be a copper clad laminate, a copper film or sheet, or other conductive layer.

While the conductive layer 408 of FIG. 4 is attached to the second glass layer 204, examples disclosed herein are not limited thereto. The conductive layer 408 can be attached to a different layer (e.g., the first glass layer 202 or other glass layers coupled thereto) in other examples.

FIG. 4G illustrates the glass core 200 after bond material 410 is removed from the conductive layer 408 that is adjacent the third through-holes 406 to expose the conductive layer 408. In some examples, the bond material 410 is removed using a self-aligning dry etch process. For example, the second glass layer 204 can implement or otherwise act as a mask and a dry-etch process can be applied from the fourth surface 218 of the second glass layer 204 to expose the conductive layer 408. However, the bond material 410 can be removed using any suitable process.

FIG. 4H illustrates the glass core 200 after the through-holes 402, 404, 406 have been plated (e.g., filled, metalized, etc.) with the conductive material 226 to form the TGVs 224. In particular, respective ones of the through-holes 402, 404, 406 for the TGVs 224 are plated together using the example multi-layer fill method disclosed herein. Relative to traditional plating processes, the multi-layer fill method illustrated in FIG. 4H results in less stresses in the TGVs 224 during fabrication thereof. For example, a traditional plating method includes deposition of a seed layer on walls 414 of the through-holes 402, 404, 406 followed by deposition of the conductive material 226. The multi-layer fill method disclosed herein is a different approach to fabricating TGVs from what has been done in the past because the seed layer can be omitted. By omitting the seed layer, the multi-layer fill method disclosed herein results in less stresses in the glass layers 202, 204 during fabrication of the TGVs 224.

During a plating process using the multi-layer fill method, the through-holes 402, 404, 406 are filled with the plated metal along a direction that is parallel to the TGVs 224 (e.g., along an axial length of the TGVs) rather than laterally (e.g., rather than radially inward from a seed layer). As a result, a gap(s) (e.g., an air gap, an air pocket, etc.) can develop in one or more of the TGVs 224. For example, as illustrated in FIG. 4H, an example gap 416 is formed in a first TGV 224a of the glass core 200, and extends from a first wall 414a defining the first TGV 224a. More specifically, as illustrated in the enlarged view of FIG. 4H, the gap 416 of FIG. 4H is in a corresponding third via 232a and extends from the first wall 414a at a shoulder defined where the dielectric material 206 overhangs the third via 232a.

FIG. 4I illustrates the glass core 200 after the conductive layer 408 and the bond material 410 are removed. In some examples, the second surface 212 of the first glass layer 202 can be planarized after the TGVs 224 are plated to remove excess conductive material (e.g., overburden) formed during the plating process. Further, in some examples, the third surface 216 of the second glass layer 204 can also be planarized to ensure the TGVs 224 are substantially flush with the third surface 216 of the second glass layer 204.

FIGS. 5A-5R illustrate various stages of manufacture of an example multi-layer glass core (e.g., the glass core 200 of FIG. 2, the glass core 300 of FIG. 3, etc.) in accordance with teachings disclosed herein. For the sake of simplicity, the various stages of manufacture of FIGS. 5A-5R are illustrated and described in relation to the glass core 300 of FIG. 3. However, aspects described herein can be applied to manufacture other stacked glass cores disclosed herein. For purposes of explanation, the various stages of manufacture illustrated in FIGS. 5A-5R have been simplified to produce one glass core. However, aspects described in relation to FIGS. 5A-5R can be applied at the panel-level or wafer-level such that the glass core 200 can be singulated (e.g., separated) from other glass cores manufactured on a glass panel or wafer.

Many of processes of the stages of manufacture represented in FIGS. 5A-5R are substantially some of the processes of the stages of manufacture represented in FIGS. 4A-4I. As such, those processes will not be described in detail again below. However, additional fabrication processes not discussed in connection with FIGS. 4A-4I are detailed in connection with FIGS. 5A-5R.

Turning in detail to the drawings, FIGS. 5A-5R are cross-sectional illustrations of the example glass core 300 of FIG. 3 at various manufacturing stages. FIG. 5A illustrates a first glass panel 500 (e.g., a glass sheet or wafer) that includes the first glass layer 302 of FIG. 3. That is, the glass core 300 of FIG. 3 is fabricated on and singulated from the first glass panel 500 to form the first glass layer 302 of the glass core 300. The first glass panel 500 includes a first surface 502 and a second surface 504 opposite the first surface 502.

FIG. 5B illustrates the glass core 300 after an example first trench 506 (e.g., a recess, a cavity, a channel, etc.) is formed in the first glass panel 500. In particular, the first trench 506 is generated along a designated saw street of the glass core 300. The designated saw street for the glass core 300 defines an edge of the glass core 300 and a corresponding package substrate. The first trench 506 illustrated in FIG. 5B at least partially borders (e.g., delineates, outlines, etc.) the first glass layer 302. Further, the first trench 506 extends through the first glass panel 500 (e.g., between the first surface 502 and the second surface 504).

In this example, the first trench 506 does extend entirely around a perimeter (e.g., the first edge) of the first glass layer 302. Rather, as discussed in greater detail in relation to FIG. 6, the first trench 506 extends along a portion of the first edge of the first glass layer 302 such that the first glass layer 302 remains attached to the rest of the first glass panel 500 during manufacture of the glass core 300 (e.g., at least until the singulation process). After the first trench 506 is formed, at least a portion of one or more of the first lateral surfaces 312 of the first glass layer 302 are revealed. In other words, the first trench 506 at least partially defines the first lateral surfaces 312 of the first glass layer 302.

While one first trench 506 is illustrated in the example first glass panel 500 of FIG. 5B, the first glass panel 500 can include more than one first trench 506 in other examples. In some examples, the first trench 506 extends around more than one side of the first glass layer 302. In some examples, one first trench 506 can be generated at least partially around the first glass layer 302. In some examples, more than one first trench 506 can be generated around the first glass layer 302 such that each first trench 506 at least partially extends around the first glass layer 302.

FIG. 5C illustrates example first through-holes 508 formed in the first glass layer 302 (e.g., the first glass panel 500). In this example, the first through-holes 508 correspond to the first vias 338 of the glass core 300 of FIG. 3. In the illustrated example of FIGS. 5A-5R, the vias 338, 340, 342 of the glass core 300 are filled in separate plating processes.

FIG. 5D illustrates the first glass panel 500 attached to a carrier 510. In particular, the carrier 510 of FIG. 5D is attached to the second surface 504 of the first glass panel 500, which corresponds to the second surface 310 of the first glass layer 302.

FIG. 5E illustrates the first glass panel 500 after a resist material 512 is deposited on the first surface 502 of the first glass panel 500. FIG. 5F illustrates the first glass panel 500 after removal of the resist material 512 adjacent the first through-holes 508. In particular, a first portion of the resist material 512 that is adjacent to or overhangs the first through-holes 508 is removed while a second portion of the resist material 512 that is adjacent to or overhangs the first trench 506 is retained. The removal of the first portion of the resist material 512 reveals the first through-holes 508. However, the first trench 506 remains covered by the second portion of the resist material 512.

FIG. 5G illustrates the first glass panel 500 after the first through-holes 508 have been plated (e.g., filled, metalized, etc.) with the conductive material 226. In particular, FIG. 5G illustrates the first glass layer 302 after the conductive material 226 is deposited to fill or plate the first through-holes 508 to form the first vias 338.

FIG. 5H illustrates the first glass panel 500 after the second portion of the resist material 512 has been removed. The removal of the second portion of the resist material 512 reveals the first trench 506. FIG. 5I illustrates the first glass panel 500 after the carrier 504 has been removed.

FIG. 5J illustrates the first glass panel 500 after the dielectric material 306 has been deposited thereon. The dielectric material 306 is deposited on the first surface 502 of the first glass panel 500 such that the dielectric material 306 is in contact with the first surface 308 of the first glass layer 302. Further, the dielectric material 306 is deposited in the first trench 506 such that the dielectric material 306 is in contact with the first lateral surfaces 312 of the first glass layer 302.

FIG. 5K illustrates the dielectric material 306 after example second through-holes 514 are formed therein. In this example, the second through-holes 514 correspond to the second vias 340 of the glass core 300 of FIG. 3. In other words, dielectric material 306 that is adjacent to the first vias 338 is removed (e.g., drilled) to reveal the second through-holes 514. As previously mentioned, the vias 338, 340, 342 of the glass core 300 of FIG. 3 are filled in separate plating processes. In some examples, a seed material or layer can be deposited on the dielectric material 306 (e.g., in the second through-holes 514) to aid in filling the second through-holes 514. In some examples, the seed material is omitted such that the second through-holes 514 can be plated using conductive material 226 in the first vias 338. Because

FIG. 5L illustrates the first glass panel 500 after the second through-holes 514 have been plated (e.g., filled, metalized, etc.) with the conductive material 226. In particular, FIG. 5L illustrates the first glass layer 302 after the conductive material 226 is deposited to fill or plate the second through-holes 514 to form the second vias 340. Further, in this example, any excess amount of the conductive material 226 and seed material on the outer surface of the dielectric material 306 is removed (e.g., via planarization).

FIG. 5M illustrates the first glass panel 500 after the adhesive material 320 is deposited onto the first glass panel 500 (e.g., the first glass layer 302) having the dielectric material 306 thereon. More specifically, the adhesive material 320 is deposited (e.g., laminated) onto the dielectric material 306.

FIG. 5N illustrates an example second glass panel 518 (e.g., a glass sheet or wafer) coupled to the first glass panel 500 via the adhesive material 320. The second glass panel 518 includes the second glass layer 304 of FIG. 3. Like the first glass layer 302 of the first glass panel 500, the second glass layer 304 is singulated from the second glass panel 518 to form the glass core 300. The second glass panel 518 includes a third surface 520 and a fourth surface 522 opposite the third surface 520. As illustrated in FIG. 5N, the fourth surface 522 of the second glass panel 518 is attached to the adhesive material 320.

The second glass panel 518 of FIG. 5N is pre-patterned with example third through-holes 524. That is, the third through-holes 524 are formed through the second glass panel 518 (e.g., the second glass layer 304) and correspond to the third vias 342 of the glass core 300 of FIG. 3.

The second glass panel 518 of FIG. 5N is pre-patterned with an example second trench 526 (e.g., a recess, a cavity, a channel, etc.). The second trench 526 of FIG. 5N is substantially similar to the first trench 506 in the first glass panel 500 (FIG. 5B). For example, the second trench 526 is generated along the designated saw street that defines the edge of the glass core 300 and a corresponding package substrate, and at least partially borders (e.g., delineates, outlines, etc.) the second glass layer 304. However, the second trench 526 can differ from the first trench 506 in other examples. Like the first glass panel 500, the second glass panel 518 can include one second trench 526 or more than one second trench 526.

In this example, the second trench 526 does not extend entirely around a perimeter (e.g., the second edge) of the second glass layer 304, but extends along a portion of the second edge of the second glass layer 304 such that the second glass layer 304 remains attached to the second glass panel 518 before attachment to the first glass panel 500. After the second trench 526 is formed, at least a portion of one or more of the second lateral surfaces 318 of the second glass layer 304 are revealed. In other words, the second trench 526 at least partially defines the second lateral surfaces 318 of the second glass layer 304.

FIG. 5O illustrates the glass core 300 after the adhesive material 320 is removed. In particular, the adhesive material 320 is removed from the dielectric material 306 within the second trench 526 and within the third through-holes 524 to expose the conductive material 226 in the dielectric material 306. In some examples, the adhesive material 320 is removed from within the third through-holes 524, but remains within the second trench 526. In some examples, the adhesive material 320 is litho-definable. In some such examples, the adhesive material 320 can be removed using photolithography. In other examples, the adhesive material 320 can be removed using a dry-etching process. It is understood, however, that the adhesive material 320 can be removed using any suitable removal process.

FIG. 5P illustrates the second glass panel 518 after the third through-holes 524 have been plated (e.g., filled, metalized, etc.) with the conductive material 226 to form the third vias 342.

FIG. 5Q illustrates the second glass panel 518 after the buffer material 322 has been deposited thereon. The buffer material 322 is deposited on the third surface 520 of the second glass panel 518 such that the buffer material 322 is in contact with the third surface 314 of the second glass layer 304 and deposited in the second trench 526 such that the buffer material 322 is in contact with the second lateral surfaces 318 of the second glass layer 304. Further, as illustrated in FIG. 5Q, the interconnects 350 are formed in the buffer material 322.

FIG. 5R illustrates a singulation saw process that is to occur along the designated cut lines or saw streets 530 to singulate the glass core 300 of FIG. 3.

FIG. 6 is a plan view of the first glass panel 500 of FIG. 5C. However, aspects described in reference to FIG. 6 can also be applicable to the second glass panel 518 of FIG. 5N. As illustrated in FIG. 6, the first glass layer 302 of the first glass core 300 is part of the first glass panel 500 prior to singulation. The first through-holes 402 are cavities that extend into the first surface 308 of the first glass layer 302.

As illustrated in FIG. 6, the first trench 506 extends along a portion of the first glass layer 302. In this example, an example third trench 602 extends around another portion of the first glass layer 302. The trenches 506, 602 reveal or define the first lateral surfaces 312 of the first glass layer 302. In other examples, the third trench 602 can be omitted. In other examples, one or more trenches 506, 602 can extend in additional or alternative directions such that the first glass layer 302 remains at least partially connected to the first glass panel 500.

As discussed above, the trenches 506, 602 are aligned with saw streets 530 that define the outer lateral surfaces 330, 332 of the core 300 when singulated. As illustrated in FIG. 6, an example glass protrusion 604 (e.g., extension, overhang, protuberance, etc.) extends from a first one of the first lateral surfaces 312 of the first glass layer 302 outwards towards the saw streets 530. While not illustrated in FIG. 6, the dielectric material 306 will be in contact with third lateral surfaces 606 of the glass protrusion 604 that are substantially parallel relative to the first lateral surface 312 of the first glass layer 302.

In some examples, when the first glass layer 302 (e.g., the glass core 300) is singulated, the glass protrusion 604 will have an outer lateral surface 608 that is substantially parallel with the outer lateral surfaces 330, 332 of the dielectric material 306 and the buffer material 322 (e.g., as defined by the saw streets 530). Further, the outer lateral surfaces 330, 332, 608 of the dielectric material 306, the buffer material 322, and the glass protrusion 604 define an edge or perimeter of the glass core 300. In other words, the outer lateral surfaces 330, 332, 608 of the dielectric material 306, the buffer material 322, and the glass protrusion 604 define exterior surface of the glass core 300 and a corresponding IC package substrate.

While not illustrated herein, in some examples, the glass protrusion 604 can have a thickness (e.g., defined between the first and second surfaces 502, 504 of the glass panel 500) that is substantially similar to a thickness of the first glass layer 302 (e.g., defined between the first and second surfaces 308, 310 of the first glass layer 302). For example, a first surface of the glass protrusion 604 can extend from the first surface 308 of the first glass layer 302 and a second surface of the glass protrusion 604 can extend from the second surface 310 of the first glass layer 302. In other examples, the thickness of the glass protrusion 604 can be different than the thickness of the first glass layer 302. For example, one or more of the first and second surfaces of the glass protrusion 604 can be offset relative to a respective one of the first surface and second surfaces 308, 310 of the first glass layer 302.

FIGS. 7A-7T illustrate various stages of manufacture of an example multi-layer glass core (e.g., the glass core 200 of FIG. 2, the glass core 300 of FIG. 3, etc.) in accordance with teachings disclosed herein. The stages of manufacture represented in FIGS. 7A-7T are similar to the stages of manufacture represented in FIGS. 5A-5R. However, additional fabrication operations not discussed in connection with FIGS. 5A-5R are detailed in connection with FIGS. 7A-7T.

FIG. 7A illustrates the first glass panel 500 having the first surface 502 and including the first glass layer 302. The first glass panel 500 of FIG. 7A also includes a fifth surface 702 that is opposite the first surface 502 of the first glass panel 500 of FIG. 7A.

FIG. 7B illustrates the first glass panel 500 after an example first trench 706 (e.g., a recess, a cavity, a channel, etc.) is formed in the first glass panel 500 along a designated saw street (e.g., the saw street 530 of FIG. 5R) of the glass core 300. Like the first trench 506 of FIG. 5B, the first trench 706 of FIG. 7B at least partially borders (e.g., delineates, outlines, etc.) the first glass layer 302. However, unlike the first trench 506 of FIG. 5B, the first trench 706 of FIG. 7B does not extend through the first glass panel 500. Rather, the first trench 706 of FIG. 7B extends from the first surface 502 of the first glass panel 500 to a recessed surface 704 that is between the first and fifth surfaces 502, 702. In particular, the first trench 706 extends a distance 708 into the first surface 502 that is less than a thickness 710 of the first glass panel 500, which extends between the first and fifth surfaces 502, 702. In some examples, the distance 708 is in a range between approximately 60% of the thickness 710 and approximately 90% of the thickness 710. For example, the distance 708 can be relatively large when the first glass panel 500 is positioned on a carrier (e.g., the carrier 510) prior to forming the trench 706. However, the distance 708 can be larger (e.g., more than 90%) or smaller (e.g., less than 60%) in other examples. In some examples, the distance 708 at least partially depends on the thickness 710.

In some examples, the first trench 706 extends entirely around a perimeter (e.g., the first edge) of the first glass layer 302. In particular, because the first trench 706 of FIG. 7B does not extend through an entirety of the thickness 710 the first glass panel 500, the first glass layer 302 remains attached to the first glass panel 500 even when the first trench 706 extends along the entire perimeter of the first glass layer 302. After the first trench 506 is formed, the first lateral surfaces 312 of the first glass layer 302 are revealed.

FIGS. 7C-7J illustrate stages of manufacture that are substantially similar to the stages of manufacture represented in FIGS. 5C-5J, respectively.

FIG. 7K illustrates the glass panel 500 after the fifth surface 702 of the first glass panel 500 is planarized to reveal the first dielectric material 306 in the first trench 706. More specifically, the fifth surface 702 of the first glass panel 500 is planarized to reveal another surface (e.g., the second surface 504) of the first glass panel 500 that is between the first and second surfaces 502, 702 of the first glass panel 500. As previously mentioned, the second surface 504 corresponds to the second surface 310 of the first glass layer 302. In other words, a planarization process is applied to the fifth surface 702 of the first glass panel 500 to reveal the second surface 310 of the first glass layer 302. This planarization process removes the remaining portion of the glass panel 500 that was aligned with the trench 706 such that the first glass layer 302 is completely isolated from the rest of the glass panel 500. However, in this example, the first glass panel 300 is retained in place relative to the rest of the glass panel 500 due to the presence of the dielectric material 306.

FIGS. 7L-7O illustrate stages of manufacture that are substantially similar to the stages of manufacture represented in FIGS. 5K-5N, respectively. For example, the second glass panel 518 (e.g., a glass sheet or wafer) is coupled to the first glass panel 500 via the adhesive material 320 such that the fourth surface 522 of the second glass panel 518 is attached to the adhesive material 320. However, the second glass panel 518 (e.g., a glass sheet or wafer) illustrated in FIG. 7O includes a sixth surface 712 opposite the fourth surface 522.

The second glass panel 518 of FIG. 7O is pre-patterned with an example second trench 714 (e.g., a recess, a cavity, a channel, etc.) that is similar to the first trench 706 in the first glass panel 500 of FIG. 7B. For example, like the first trench 706 of FIG. 7B, the second trench 714 of FIG. 7O does not extend through the second glass panel 518. Rather, the second trench 714 of FIG. 7O extends a distance into the fourth surface 522 of the second glass panel 518 that is less than a thickness 716 of the second glass panel 518. The second trench 714 at least partially defines the second lateral surfaces 318 of the second glass layer 304.

FIG. 7P illustrates the glass core 300 after the adhesive material 320 is removed is removed within the third through-holes 524. As illustrated in FIG. 7P, the adhesive material 320 remains in the trench 714.

FIG. 7Q illustrates the second glass panel 518 after the third through-holes 524 have been plated (e.g., filled, metalized, etc.) with the conductive material 226 to form the third vias 342.

FIG. 7R illustrates the second glass panel 518 after the sixth surface 712 is planarized to reveal the second trench 714. The planarization of the sixth surface 712 of the second glass panel 518 reveals another surface (e.g., the third surface 520) of the second glass panel 518 that is between the fourth and sixth surfaces 522, 712 of the second glass panel 518. As previously mentioned, the third surface 520 corresponds to the third surface 314 of the second glass layer 302. Thus, a planarization process is applied to the sixth surface 712 of the second glass panel 518 to reveal the second surface 310 of the second glass layer 304. This planarization process removes the remaining portion of the glass panel 518 that was aligned with the trench 714 such that the second glass layer 302 is completely isolated from the rest of the glass panel 518. However, in this example, the second glass layer 304 is retained in place relative to the rest of the glass panel 518 due to the presence of the dielectric material 306.

FIG. 7S illustrates the second glass panel 518 after the buffer material 322 has been deposited thereon. The buffer material 322 is deposited on the third surface 520 of the second glass panel 518 such that the buffer material 322 is in contact with the third surface 314 of the second glass layer 304. Further, the buffer material 322 is deposited in the second trench 714 such that the buffer material 322 is in contact with the second lateral surfaces 318 of the second glass layer 304. Further, as illustrated in FIG. 7S, the interconnects 350 are formed in the buffer material 322.

As illustrated in FIG. 7S, a portion of the adhesive material 320 remains in the trench 714. Thus, the buffer material 322 does not contact the dielectric material 306 to define the interface 334 (FIG. 3). In other examples, the adhesive material 320 in the trench 714 can be removed prior to deposition of the buffer material 322.

FIG. 7T illustrates a singulation saw process that is to occur along the designated saw streets 530 to singulate the glass core 300 of FIG. 3.

FIG. 8 is a plan view of the first glass panel 500 of FIG. 7C. However, aspects described in reference to FIG. 8 can also be applicable to the second glass panel 518 of FIG. 7O. As illustrated in FIG. 8, the first glass layer 302 of the first glass core 300 is part of the first glass panel 500 prior to singulation.

In this example, the trench 714 extends around a perimeter or edge of the first glass layer 302. In particular, because the trench 714 extends to the recessed surface 704 (which is shaded darker in FIG. 8 than other portions of the glass panel 500 for purposes of explanation), the first glass layer 302 remains in contact with the first glass panel 500. The trench 714 reveals or define the first lateral surfaces 312 (e.g., the first edge) of the first glass layer 302. When fifth surface 702 (FIG. 7C) is planarized, each first lateral surface 312 of the first glass layer 302 will be enclosed in a protective layer 324 (FIG. 3). Further, a saw process used to singulate the glass core 300 will avoid contact with the glass layers 302, 304.

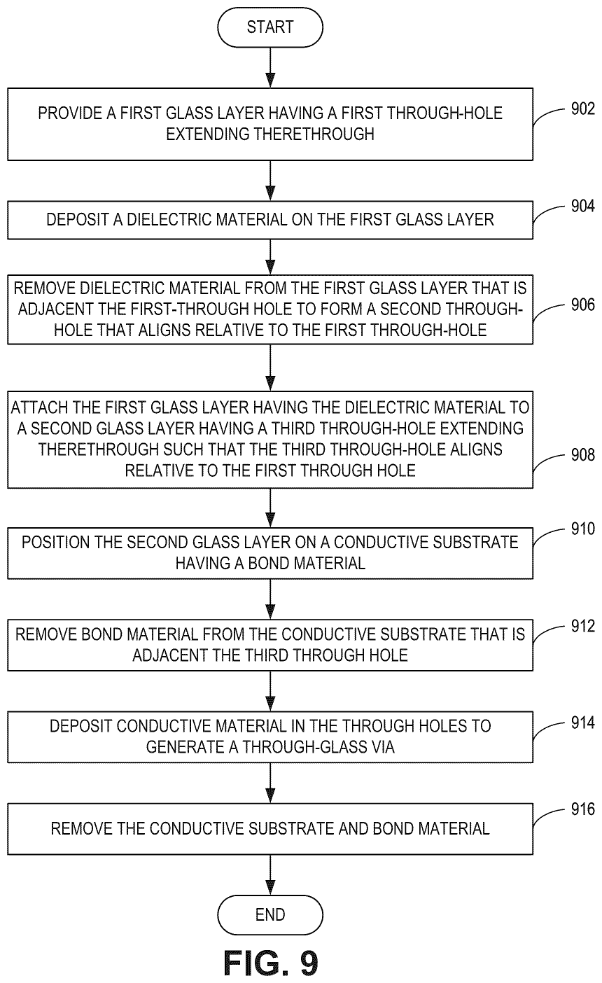

FIG. 9 is a flowchart representative of an example method 900 that may be performed to fabricate any one of the example glass cores disclosed herein, such as the glass core 200 of FIG. 2 as represented by the example stages of manufacture shown in FIGS. 4A-4I, the glass core 300 of FIG. 3 as represented by the example stages of manufacture shown in FIGS. 5A-5R, 6, 7A-7T and 8, or another glass core disclosed herein. In some examples, some or all of the operations outlined in the example method of FIG. 9 are performed automatically by equipment that is programmed to perform the operations. Although the example method of manufacture is described with reference to the flowchart illustrated in FIG. 9, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

For purposes of explanation, the example process of FIG. 9 will be described primarily with reference to the glass core 200 of FIG. 2. However, the following discussion applies similarly to any other glass core disclosed herein.

The example method beings at block 902 by providing a first glass layer having a first through-hole extending therethrough. For example, the method can include providing the first glass layer 202 having the first through-hole 402 extending therethrough. At block 904, the method includes depositing dielectric material (e.g., dielectric material 206 of FIGS. 2 and 4C-4I) on the first glass layer 202. For example, the method can include depositing the dielectric material 206 on the first surface 210 of the first glass layer 202. In some examples, the method can include depositing the dielectric material 206 on an edge of the first glass layer 202 defined between the first and second surfaces 210, 212.

At block 906, the method includes removing the dielectric material 206 from the first glass layer 202 that is adjacent the first through-hole 402 to form a second through-hole (e.g., second through-hole 404 of FIGS. 2 and 4D-4I) that aligns relative to the first through-hole 402. As previously discussed, the second through-holes 404 can be formed using a self-aligning etch process. For example, the first glass layer 202 can be used as a mask (e.g., a photomask) such that a dry etch process can be applied from the second surface 212 of the first glass layer 202. However, the second through-holes 404 can be formed using any suitable process.

At block 908, the method includes attaching the first glass layer 202 having the dielectric material 206 to a second glass layer having a third through hole extending therethrough such that the third through-hole aligns relative to the first through-hole. For example, the method can include coupling the first glass layer 202 to the second glass layer 204 (FIGS. 2 and 4E-4I) that is pre-patterned with the third through-hole 406 (FIGS. 2 and 4E-4I) extending therethrough. In some examples, the third through-hole 406 has a second diameter 236 that is larger than the first through-hole 402 of the first glass layer 202. In doing so, the first through-hole 402 and the third through-hole 406 can align even when there is an offset error during an alignment process.

At block 910, the method includes positioning the second glass layer 204 on a conductive substrate having a bond material. For example, the third surface 216 of the second glass layer 204 can be coupled to the conductive substrate 408 (FIGS. 4F-4G) such that the bond material 410 (FIGS. 4F-4G) is positioned between the second glass layer 204 and the conductive substrate 408. The conductive substrate 408 implements a temporary carrier that aids in the plating of the TGVs 224. For example, the conductive substrate 408 serves as a conductive base on which a plating process can be applied to grow the conductive material 226.

At block 912, the method includes removing bond material 410 from the conductive substrate 408 that is adjacent the third through-hole 406. For example, the removing of the bond material 410 exposes the conductive substrate 408 within the third through-holes 406 to enable plating of the TGVs without application of a seed layer. At block 914, the method includes depositing conductive material (e.g., the conductive material 226) in the through-holes 402, 404, 406 to generate a first via (e.g., the TGV 224). In this example, the TGV 224 can be plated using the multi-layer fill process disclosed herein. However, the TGV 224 can be plated in separate steps in other examples. At block 916, the method includes removing the conductive substrate 408 and the bond material 410.

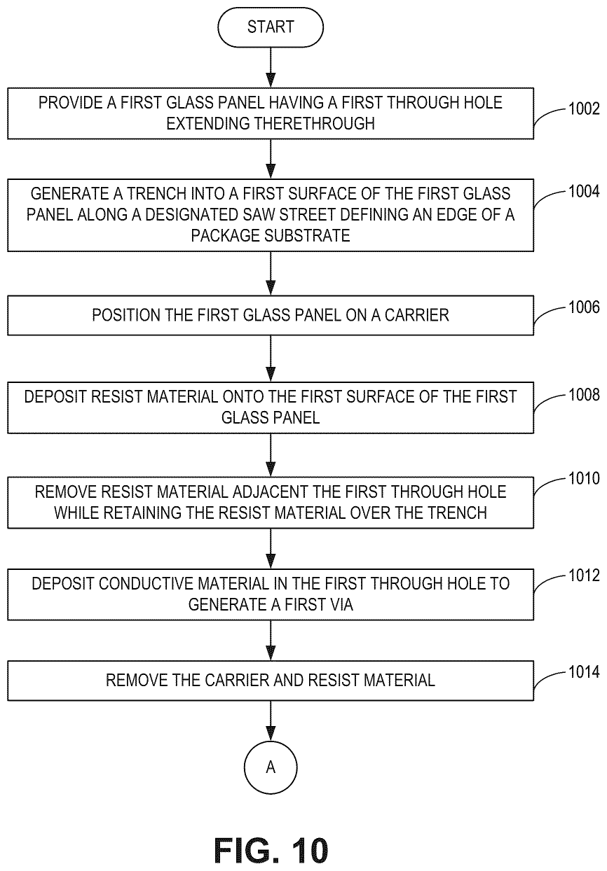

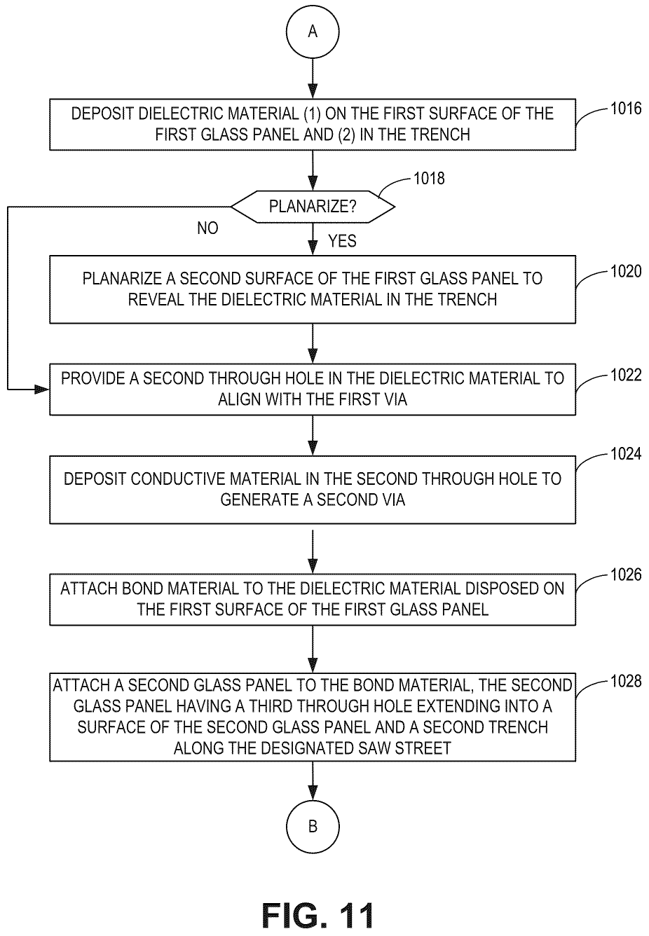

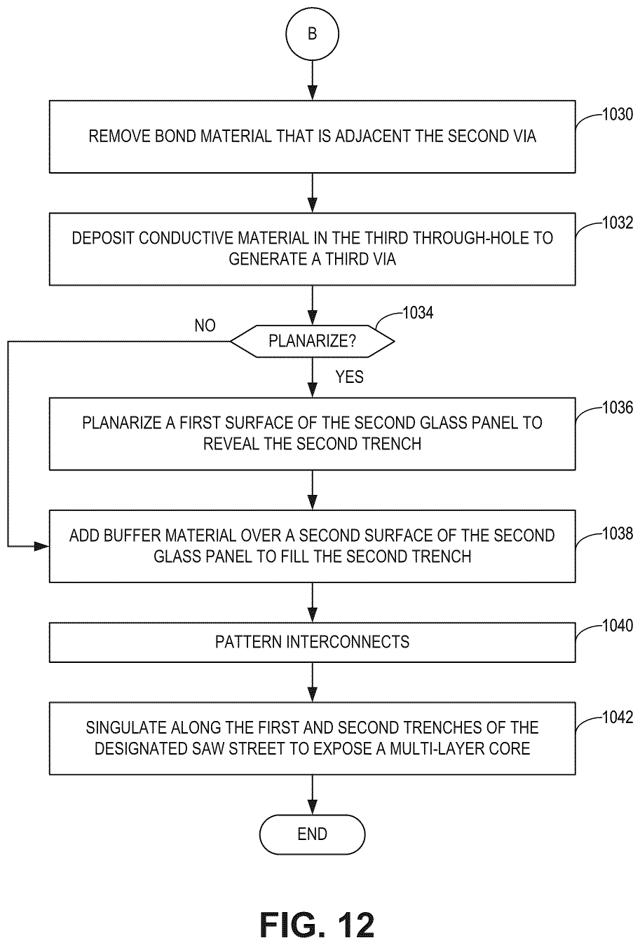

FIGS. 10-12 are flowcharts representative of an example method of fabricating an example multi-layer glass core disclosed herein, such as the glass core 200 of FIG. 2 as represented by the example stages of manufacture shown in FIGS. 4A-4I, the glass core 300 of FIG. 3 as represented by the example stages of manufacture shown in FIGS. 5A-5R, 6, 7A-7T and 8, or another glass core disclosed herein. In some examples, some or all of the operations outlined in the example method of FIGS. 10-12 are performed automatically by fabrication equipment that is programmed to perform the operations. Although the example method of manufacture is described with reference to the flowchart illustrated in FIGS. 10-12, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

For purposes of explanation, the example process of FIGS. 10-12 will be described primarily with reference to the glass core 300 of FIG. 3. However, the following discussion applies similarly to any other glass core disclosed herein.

The process begins with block 1002, which includes providing a first glass panel 500 having a first through-hole 508 extending therethrough.

At block 1004, the method includes generating a trench into a first surface 502 of the first glass panel 500 along a designated saw street defining an edge of a package substrate. The trench can correspond to any of the example first trenches 506, 602, 706 disclosed herein.

At block 1006, the method includes positioning the first glass panel 500 on a carrier (e.g., the carrier 510 of FIGS. 5D-5H). At block 1008, the method includes depositing resist material (e.g., the resist material 512 of FIGS. 5E-5G) onto the first surface 502 of the first glass panel 500. At block 1010, the method includes removing resist material 512 adjacent the first through-hole 508 while retaining the resist material 512 over the trench 506, 602, 706.

At block 1012, the method includes depositing conductive material (e.g., the conductive material 226) in the first through-hole 508 to generate a first via (e.g., the first via 338). In particular, removing the resist material 512 adjacent the first through-hole 508 exposes the first through-hole 508 to facilitate plating of a first via (e.g., the first via 338). In some examples, a seed layer is deposited in the first through-hole 508 prior to deposition of the conductive material 226. At block 1014, the method includes removing the carrier 510 and the resist material 512.

At block 1016, the method includes depositing dielectric material (e.g., the dielectric material 306) (1) on the first surface 502 of the first glass panel 500 and (2) in the trench 506, 602, 706. In doing so, the first lateral surfaces 312 of a first glass layer (e.g., the first glass layer 302) are overlaid with the dielectric material 306.

At block 1018, the method includes determining whether to planarize. For example, when the trench 506, 602, 706 extends through the first glass panel 500, planarization may not be needed. However, when the trench 506, 602, 706 extends into the first surface 502 of the first glass panel 500 to a recessed surface 704 (FIG. 7B-7J), a planarization process can be applied to reveal the trench 506, 602, 706. When the answer to block 1018 is YES, the method continues to block 1020, which includes planarizing a second surface (e.g., the second surface 702 of FIGS. 7A-7J) of the first glass panel 500 to reveal the dielectric material 306 in the trench 506, 602, 706.

When the answer to block 1018 is NO, the method continues to block 1022. At block 1022, the method includes providing a second through-hole (e.g., the second through-hole 514 of FIGS. 5K and 7L) in the dielectric material 306 to align with the first via 338. At block 1024, the method includes depositing conductive material 226 in the second through-hole 514 to generate a second via (e.g., the second via 340). In some examples, a seed layer is deposited in the second through-hole 514 prior to deposition of the conductive material 226.

At block 1026, the method includes attaching bond material to the dielectric material 306 disposed on the first surface 502 of the first glass panel 500. For example, the method can include attaching the adhesive material 320 (FIGS. 3, 5M-5R, 7N-7T) to the first surface 502 of the first glass panel 500. At block 1028, the method includes attaching a second glass panel (e.g., the second glass panel 518) to the bond material 320, the second glass layer having a third through-hole extending into a surface of the second glass panel and a second trench along the designated saw street. For example, the second glass panel 518 can be pre-patterned with a third through-hole 524 and a second trench. The second trench can correspond to any second trench 526, 714 disclosed herein. In some examples, the third through-hole 524 and the second trench 526 extend into the third surface 520 of the second glass panel 518. In some examples, the third through-hole 524 and the second trench 526 extend into the fourth surface 522 of the second glass panel 518.

At block 1030, the method includes removing bond material 320 that is adjacent the second via 340. At block 1032, the method includes depositing conductive material 226 in the third through-hole 524 to generate a third via (e.g., the third via 342). In doing so, a TGV 336 is generated through the glass core 300. In some examples, a seed layer is deposited in the third through-hole 524 prior to deposition of the conductive material 226.

At block 1034, the method includes determining whether to planarize. For example, when the second trench 526, 714 extends through the second glass panel 518, planarization may not be needed. However, when the trench 526, 714 extends has a depth that is less than a thickness 716 of the second glass panel 518, a planarization process can be applied to reveal trench 526, 714. When the answer to block 1034 is YES, the method continues to block 1036, which includes planarizing a first surface (e.g., the sixth surface 712 of FIGS. 7O-7Q) of the second glass panel 518 to reveal the second trench 526, 714.

When the answer to block 1034 is NO, the method continues to block 1038. At block 1038, the method includes adding a buffer material (e.g., the buffer material 322) over a second surface of the second glass panel 518 to fill the second trench 526, 714. For example, the method can include depositing the buffer material 322 over the third surface 520 (FIGS. 5N-5R, 7R-7T) of the second glass panel 518. The buffer material 322 is also deposited in the second trench 526, 714. In doing so, the second lateral surfaces 318 of a second glass layer (e.g., the second glass layer 304) are overlaid with the buffer material 322.

At block 1040, the method includes patterning interconnects. For example, the method can include patterning the interconnects 350 in the buffer material 322. At block 1042, the method includes singulating along the first and second trenches 506, 602, 706, 526, 714 of the designated saw street to expose a multi-layer glass core (e.g., the glass core 300). During singulation, a cutting process is within the first and second trenches 506, 602, 706, 526, 714 such that a protective layer 324 is positioned between the cutting process and the later surfaces 312, 318 (e.g., the edges) of the glass layer 302, 304.

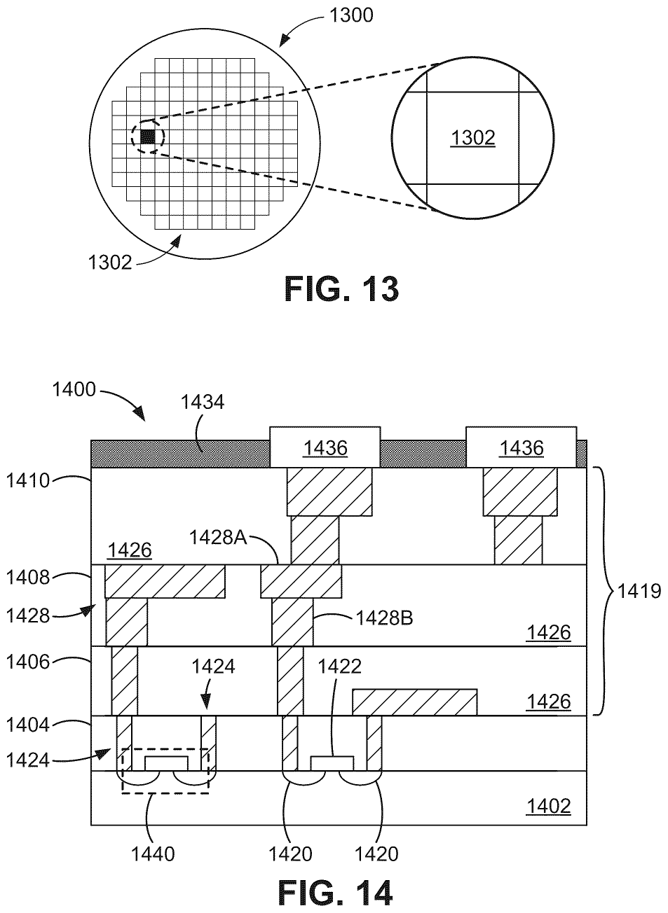

FIG. 13 is a top view of a wafer 1300 and dies 1302 that may be included in the IC package 100 of FIG. 1 (e.g., as any suitable ones of the dies 106, 108). The wafer 1300 includes semiconductor material and one or more dies 1302 having circuitry. Each of the dies 1302 may be a repeating unit of a semiconductor product. After the fabrication of the semiconductor product is complete, the wafer 1300 may undergo a singulation process in which the dies 1302 are separated from one another to provide discrete “chips.” The die 1302 includes one or more transistors (e.g., some of the transistors 1440 of FIG. 14, discussed below), supporting circuitry to route electrical signals to the transistors, passive components (e.g., traces, resistors, capacitors, inductors, and/or other circuitry), and/or any other components. In some examples, the die 1302 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 1302. For example, a memory array of multiple memory circuits may be formed on a same die 1302 as programmable circuitry (e.g., the processor circuitry 2302 of FIG. 23) and/or other logic circuitry. Such memory may store information for use by the programmable circuitry. An example IC package may be manufactured using a die-to-wafer assembly technique in which some dies are attached to a wafer 1300 that includes others of the dies, and the wafer 1300 is subsequently singulated.

FIG. 14 is a cross-sectional side view of an IC device 1400 that may be included in an IC package whose substrate includes one or more glass cores 130, 200, 300 (e.g., as discussed above with reference to FIGS. 1-13), in accordance with any of the examples disclosed herein. One or more of the IC devices 1400 may be included in one or more dies 1302 (FIG. 13). The IC device 1400 may be formed on a die substrate 1402 (e.g., the wafer 1300 of FIG. 13) and may be included in a die (e.g., the die 1302 of FIG. 13). The die substrate 1402 may be a semiconductor substrate including semiconductor materials including, for example, n-type or p-type materials systems (or a combination of both). The die substrate 1402 may include, for example, a crystalline substrate formed using a bulk silicon or a silicon-on-insulator (SOI) substructure. In some examples, the die substrate 1402 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1402. Although a few examples of materials from which the die substrate 1402 may be formed are described here, any material that may serve as a foundation for an IC device 1400 may be used. The die substrate 1402 may be part of a singulated die (e.g., the dies 1302 of FIG. 13) or a wafer (e.g., the wafer 1300 of FIG. 13).

The IC device 1400 may include one or more device layers 1404 disposed on and/or above the die substrate 1402. The device layer 1404 may include features of one or more transistors 1440 (e.g., metal oxide semiconductor field-effect transistors (MOSFETs)) formed on the die substrate 1402. The device layer 1404 may include, for example, one or more source and/or drain (S/D) regions 1420, a gate 1422 to control current flow between the S/D regions 1420, and one or more S/D contacts 1424 to route electrical signals to/from the S/D regions 1420. The transistors 1440 may include additional features not depicted for the sake of clarity, such as device isolation regions, gate contacts, and the like. The transistors 1440 are not limited to the type and configuration depicted in FIG. 14 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1440 may include a gate 1422 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1440 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1440 along the source-channel-drain direction, the gate electrode may include a U-shaped structure that includes a bottom portion substantially parallel to the surface of the die substrate 1402 and two sidewall portions that are substantially perpendicular to the top surface of the die substrate 1402. In other examples, at least one of the metal layers that form the gate electrode may be a planar layer that is substantially parallel to the top surface of the die substrate 1402 and does not include sidewall portions substantially perpendicular to the top surface of the die substrate 1402. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1420 may be formed within the die substrate 1402 adjacent to the gate 1422 of corresponding transistor(s) 1440. The S/D regions 1420 may be formed using an implantation/diffusion process or an etching/deposition process, for example. In the former process, dopants such as boron, aluminum, antimony, phosphorous, or arsenic may be ion-implanted into the die substrate 1402 to form the S/D regions 1420. An annealing process that activates the dopants and causes them to diffuse farther into the die substrate 1402 may follow the ion-implantation process. In the latter process, the die substrate 1402 may first be etched to form recesses at the locations of the S/D regions 1420. An epitaxial deposition process may then be carried out to fill the recesses with material that is used to fabricate the S/D regions 1420. In some implementations, the S/D regions 1420 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1420 may be formed using one or more alternate semiconductor materials such as germanium or a group III-V material or alloy. In further examples, one or more layers of metal and/or metal alloys may be used to form the S/D regions 1420.

Electrical signals, such as power and/or input/output (I/O) signals, may be routed to and/or from the devices (e.g., transistors 1440) of the device layer 1404 through one or more interconnect layers disposed on the device layer 1404 (illustrated in FIG. 14 as interconnect layers 1406-1410). For example, electrically conductive features of the device layer 1404 (e.g., the gate 1422 and the S/D contacts 1424) may be electrically coupled with the interconnect structures 1428 of the interconnect layers 1406-1410. The one or more interconnect layers 1406-1410 may form a metallization stack (also referred to as an “ILD stack”) 1419 of the IC device 1400.

The interconnect structures 1428 may be arranged within the interconnect layers 1406-1410 to route electrical signals according to a wide variety of designs (in particular, the arrangement is not limited to the particular configuration of interconnect structures 1428 depicted in FIG. 14). Although a particular number of interconnect layers 1406-1410 is depicted in FIG. 14, examples of the present disclosure include IC devices having more or fewer interconnect layers than depicted.

In some examples, the interconnect structures 1428 may include lines 1428a and/or vias 1428b filled with an electrically conductive material such as a metal. The lines 1428a may be arranged to route electrical signals in a direction of a plane that is substantially parallel with a surface of the die substrate 1402 upon which the device layer 1404 is formed. For example, the lines 1428a may route electrical signals in a direction in and/or out of the page from the perspective of FIG. 14. The vias 1428b may be arranged to route electrical signals in a direction of a plane that is substantially perpendicular to the surface of the die substrate 1402 upon which the device layer 1404 is formed. In some examples, the vias 1428b may electrically couple lines 1428a of different interconnect layers 1406-1410 together.

The interconnect layers 1406-1410 may include a dielectric material 1426 disposed between the interconnect structures 1428, as shown in FIG. 14. In some examples, the dielectric material 1426 disposed between the interconnect structures 1428 in different ones of the interconnect layers 1406-1410 may have different compositions; in other examples, the composition of the dielectric material 1426 between different interconnect layers 1406-1410 may be the same.

A first interconnect layer 1406 (referred to as Metal 1 or “M1”) may be formed directly on the device layer 1404. In some examples, the first interconnect layer 1406 may include lines 1428a and/or vias 1428b, as shown. The lines 1428a of the first interconnect layer 1406 may be coupled with contacts (e.g., the S/D contacts 1424) of the device layer 1404.

A second interconnect layer 1408 (referred to as Metal 2 or “M2”) may be formed directly on the first interconnect layer 1406. In some examples, the second interconnect layer 1408 may include vias 1428b to couple the lines 1428a of the second interconnect layer 1408 with the lines 1428a of the first interconnect layer 1406. Although the lines 1428a and the vias 1428b are structurally delineated with a line within each interconnect layer (e.g., within the second interconnect layer 1408) for the sake of clarity, the lines 1428a and the vias 1428b may be structurally and/or materially contiguous (e.g., simultaneously filled during a dual-damascene process) in some examples.

A third interconnect layer 1410 (referred to as Metal 3 or “M3”) (and additional interconnect layers, as desired) may be formed in succession on the second interconnect layer 1408 according to similar techniques and/or configurations described in connection with the second interconnect layer 1408 or the first interconnect layer 1406. In some examples, the interconnect layers that are “higher up” in the metallization stack 1419 in the IC device 1400 (i.e., further away from the device layer 1404) may be thicker.

The IC device 1400 may include a solder resist material 1434 (e.g., polyimide or similar material) and one or more conductive contacts 1436 formed on the interconnect layers 1406-1410. In FIG. 14, the conductive contacts 1436 are illustrated as taking the form of bond pads. The conductive contacts 1436 may be electrically coupled with the interconnect structures 1428 and configured to route the electrical signals of the transistor(s) 1440 to other external devices. For example, solder bonds may be formed on the one or more conductive contacts 1436 to mechanically and/or electrically couple a chip including the IC device 1400 with another component (e.g., a circuit board). The IC device 1400 may include additional or alternate structures to route the electrical signals from the interconnect layers 1406-1410; for example, the conductive contacts 1436 may include other analogous features (e.g., posts) that route the electrical signals to external components.

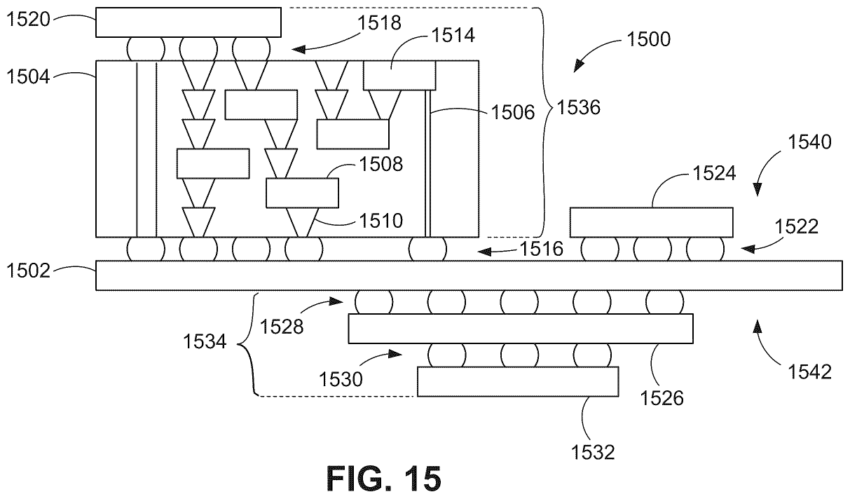

FIG. 15 is a cross-sectional side view of an IC device assembly 1500 that may include the glass core 200, 300 disclosed herein. The IC device assembly 1500 includes a number of components disposed on a circuit board 1502 (which may be, for example, a motherboard). The IC device assembly 1500 includes components disposed on a first face 1540 of the circuit board 1502 and an opposing second face 1542 of the circuit board 1502; generally, components may be disposed on one or both faces 1540 and 1542. Any of the IC packages discussed below with reference to the IC device assembly 2200 may take the form of the example IC package 100 of FIG. 1.

In some examples, the circuit board 1502 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1502. In other examples, the circuit board 1502 may be a non-PCB substrate.

The IC device assembly 1500 illustrated in FIG. 15 includes a package-on-interposer structure 1536 coupled to the first face 1540 of the circuit board 1502 by coupling components 1516. The coupling components 1516 may electrically and mechanically couple the package-on-interposer structure 1536 to the circuit board 1502, and may include solder balls (as shown in FIG. 15), male and female portions of a socket, an adhesive, an underfill material, and/or any other suitable electrical and/or mechanical coupling structure.

The package-on-interposer structure 1536 may include an IC package 1520 coupled to an interposer 1504 by coupling components 1518. The coupling components 1518 may take any suitable form for the application, such as the forms discussed above with reference to the coupling components 1516. Although a single IC package 1520 is shown in FIG. 15, multiple IC packages may be coupled to the interposer 1504; indeed, additional interposers may be coupled to the interposer 1504. The interposer 1504 may provide an intervening substrate used to bridge the circuit board 1502 and the IC package 1520. The IC package 1520 may be or include, for example, a die (the die 1302 of FIG. 13), an IC device (e.g., the IC device 1400 of FIG. 14), or any other suitable component. Generally, the interposer 1504 may spread a connection to a wider pitch or reroute a connection to a different connection. For example, the interposer 1504 may couple the IC package 1520 (e.g., a die) to a set of BGA conductive contacts of the coupling components 1516 for coupling to the circuit board 1502. In the example illustrated in FIG. 15, the IC package 1520 and the circuit board 1502 are attached to opposing sides of the interposer 1504; in other examples, the IC package 1520 and the circuit board 1502 may be attached to a same side of the interposer 1504. In some examples, three or more components may be interconnected by way of the interposer 1504.

In some examples, the interposer 1504 may be formed as a PCB, including multiple metal layers separated from one another by layers of dielectric material and interconnected by electrically conductive vias. In some examples, the interposer 1504 may be formed of an epoxy resin, a fiberglass-reinforced epoxy resin, an epoxy resin with inorganic fillers, a ceramic material, or a polymer material such as polyimide. In some examples, the interposer 1504 may be formed of alternate rigid or flexible materials that may include the same materials described above for use in a semiconductor substrate, such as silicon, germanium, and other group III-V and group IV materials. The interposer 1504 may include metal interconnects 1508 and vias 1510, including but not limited to through-silicon vias (TSVs) 1506. The interposer 1504 may further include embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art.

The IC device assembly 1500 may include an IC package 1524 coupled to the first face 1540 of the circuit board 1502 by coupling components 1522. The coupling components 1522 may take the form of any of the examples discussed above with reference to the coupling components 1516, and the IC package 1524 may take the form of any of the examples discussed above with reference to the IC package 1520.

The IC device assembly 1500 illustrated in FIG. 15 includes a package-on-package structure 1534 coupled to the second face 1542 of the circuit board 1502 by coupling components 1528. The package-on-package structure 1534 may include a first IC package 1526 and a second IC package 1532 coupled together by coupling components 1530 such that the first IC package 1526 is disposed between the circuit board 1502 and the second IC package 1532. The coupling components 1528, 1530 may take the form of any of the examples of the coupling components 1516 discussed above, and the IC packages 1526, 1532 may take the form of any of the examples of the IC package 1520 discussed above. The package-on-package structure 1534 may be configured in accordance with any of the package-on-package structures known in the art.

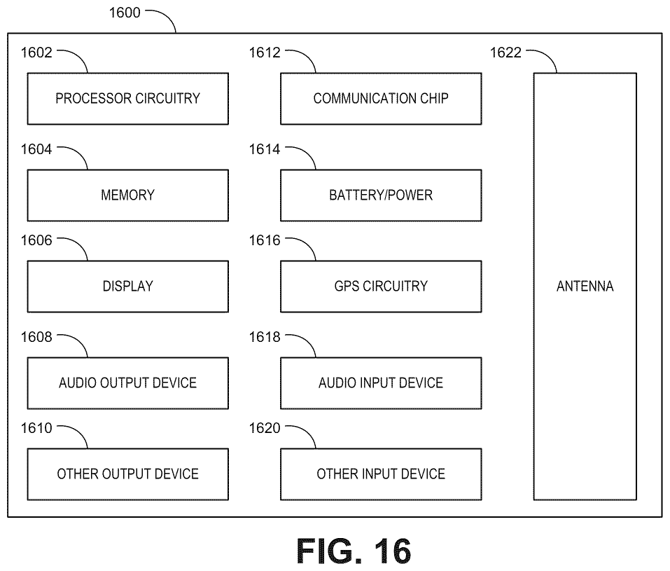

FIG. 16 is a block diagram of an example electrical device 1600 that may include one or more of the example glass cores 130, 200, 300 disclosed herein. For example, any suitable ones of the components of the electrical device 1600 may include one or more of the device assemblies 1500, IC devices 2000, or dies 1302 disclosed herein. A number of components are illustrated in FIG. 16 as included in the electrical device 1600, but any one or more of these components may be omitted or duplicated, as suitable for the application. In some examples, some or all of the components included in the electrical device 1600 may be attached to one or more motherboards. In some examples, some or all of these components are fabricated onto a single system-on-a-chip (SoC) die.

Additionally, in various examples, the electrical device 1600 may not include one or more of the components illustrated in FIG. 16, but the electrical device 1600 may include interface circuitry for coupling to the one or more components. For example, the electrical device 1600 may not include a display 1606, but may include display interface circuitry (e.g., a connector and driver circuitry) to which a display 1606 may be coupled. In another set of examples, the electrical device 1600 may not include an audio input device 1618 (e.g., microphone) or an audio output device 1608 (e.g., a speaker, a headset, earbuds, etc.), but may include audio input or output device interface circuitry (e.g., connectors and supporting circuitry) to which an audio input device 1618 or audio output device 1608 may be coupled.

The electrical device 1600 may include programmable circuitry 1602 (e.g., one or more processing devices). The programmable circuitry 1602 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1600 may include a memory 1604, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1604 may include memory that shares a die with the programmable circuitry 1602. This memory may be used as cache memory and may include embedded dynamic random access memory (eDRAM) or spin transfer torque magnetic random access memory (STT-MRAM).

In some examples, the electrical device 1600 may include a communication chip 1612 (e.g., one or more communication chips). For example, the communication chip 1612 may be configured for managing wireless communications for the transfer of data to and from the electrical device 1600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1612 may operate in accordance with other wireless protocols in other examples. The electrical device 1600 may include an antenna 1622 to facilitate wireless communications and/or to receive other wireless communications (such as AM or FM radio transmissions).

In some examples, the communication chip 1612 may manage wired communications, such as electrical, optical, or any other suitable communication protocols (e.g., the Ethernet). As noted above, the communication chip 1612 may include multiple communication chips. For instance, a first communication chip 1612 may be dedicated to shorter-range wireless communications such as Wi-Fi or Bluetooth, and a second communication chip 1612 may be dedicated to longer-range wireless communications such as global positioning system (GPS), EDGE, GPRS, CDMA, WiMAX, LTE, EV-DO, or others. In some examples, a first communication chip 1612 may be dedicated to wireless communications, and a second communication chip 1612 may be dedicated to wired communications.

The electrical device 1600 may include battery/power circuitry 1614. The battery/power circuitry 1614 may include one or more energy storage devices (e.g., batteries or capacitors) and/or circuitry for coupling components of the electrical device 1600 to an energy source separate from the electrical device 1600 (e.g., AC line power).

The electrical device 1600 may include a display 1606 (or corresponding interface circuitry, as discussed above). The display 1606 may include any visual indicators, such as a heads-up display, a computer monitor, a projector, a touchscreen display, a liquid crystal display (LCD), a light-emitting diode display, or a flat panel display.

The electrical device 1600 may include an audio output device 1608 (or corresponding interface circuitry, as discussed above). The audio output device 1608 may include any device that generates an audible indicator, such as speakers, headsets, or earbuds.

The electrical device 1600 may include an audio input device 1618 (or corresponding interface circuitry, as discussed above). The audio input device 1618 may include any device that generates a signal representative of a sound, such as microphones, microphone arrays, or digital instruments (e.g., instruments having a musical instrument digital interface (MIDI) output).

The electrical device 1600 may include GPS circuitry 1616. The GPS circuitry 1616 may be in communication with a satellite-based system and may receive a location of the electrical device 1600, as known in the art.

The electrical device 1600 may include any other output device 1610 (or corresponding interface circuitry, as discussed above). Examples of the other output device 1610 may include an audio codec, a video codec, a printer, a wired or wireless transmitter for providing information to other devices, or an additional storage device.

The electrical device 1600 may include any other input device 1620 (or corresponding interface circuitry, as discussed above). Examples of the other input device 1620 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1600 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1600 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable manufacture of improved glass cores. Certain examples disclosed herein enable manufacture of an edge-protected glass core in which lateral surfaces of a glass layer are provided with a protective layer. Examples disclosed herein also facilitate manufacture of a multi-layer glass core having stacked glass layers to reduce or limit defects in a glass core during subsequent processes. Examples disclosed herein enable the implementation of certain fabrication processes that are not conducive with traditional, single-layer glass cores due at least in part to the fragile nature of glass. Certain examples disclosed herein provide multi-layer glass cores having an increased thickness relative to single-layer glass cores, and facilitate higher aspect ratio vias relative to conventional substrate cores (e.g., single-layer glass cores, epoxy-base cores, etc.). While examples disclosed herein provide advantages specific to the implementation of package substrates of glass cores, it should be appreciated that examples disclosed herein are not limited to packages with glass cores. For instance, protective layers for cores disclosed herein can be used in conjunction with an organic core and/or in any other type of package substrate. Further examples and combinations thereof include the following:

Example 1 includes a device comprising a first glass layer including a first surface, a second surface opposite the first surface, and first lateral surfaces extending between the first and second surfaces, the first glass layer having a first via extending between the first surface and the second surface, and a dielectric material in contact with the first surface of the first glass layer and in contact with the first lateral surfaces of the first glass layer.

Example 2 includes the device of example 1, further including a second glass layer having a third surface and a fourth surface opposite the third surface, the second glass layer having a second via extending between the third and fourth surfaces, the third surface positioned adjacent the first surface of the first glass layer, the first via aligned relative to the second via.

Example 3 includes the device of example 2, wherein the first via has a first diameter and the second via has a second diameter, the first diameter being smaller than the second diameter.

Example 4 includes the package substrate of example 2, further including a third via in the dielectric material such that the third via is aligned relative to the first and second via.

Example 5 includes the device of example 4, wherein the first via has a first diameter, the second via has a second diameter that is substantially similar to the first diameter, and the third via has a third diameter that is larger than the first diameter and larger than the second diameter.

Example 6 includes the device of example 2, further including a bond material positioned between the first glass layer and the second glass layer.

Example 7 includes the device of any one of examples 2-6, further including a buffer material in contact with the fourth surface of the second glass layer and in contact with second lateral surfaces of the second glass layer that extend between the third and fourth surfaces of the second glass layer.

Example 8 includes the device of example 7, wherein outer lateral surfaces of the buffer material are substantially flush with outer lateral surfaces of the dielectric material.

Example 9 includes the device of example 7, wherein a portion of the buffer material is in contact with a portion of the dielectric material to define an interface that is substantially parallel relative to the first surface of the first glass layer.

Example 10 includes the device of any one of examples 1-9, wherein the first via includes an air gap positioned adjacent a wall of the first via.

Example 11 includes the device of any one of examples 1-10, wherein the dielectric material substantially encloses the first lateral surfaces of the first glass layer.

Example 12 includes the device of any one of examples 1-11, wherein the first glass layer includes a glass protrusion extending from a first one of the first lateral surfaces, the dielectric material is in contact with a fifth surface of the glass protrusion that is perpendicular relative to the first and second surfaces of the first glass layer.

Example 13 includes an apparatus comprising a first glass substrate having a first via extending therethrough, and first dielectric material positioned on a first edge of the first glass substrate, the first edge extending in a direction perpendicular to a first surface of the first glass substrate.

Example 14 includes the apparatus of example 13, wherein the first edge is defined by a perimeter of the first glass substrate.

Example 15 includes the apparatus of example 13, further including a second glass substrate having a second via extending therethrough, and second dielectric material positioned between the first glass substrate and the second glass substrate, the second dielectric material having a third via extending therethrough, the third via extending between the first via and the second via to electrically couple the first glass substrate and the second glass substrate.

Example 16 includes the apparatus of example 15, further including a buffer layer positioned on a second edge of the second glass substrate, the second edge of the second glass substrate being substantially parallel to the first edge of the first glass substrate.

Example 17 includes the apparatus of example 16, wherein a thickness of the first dielectric material is substantially similar to a thickness of the buffer layer.

Example 18 includes a package comprising a semiconductor die, and a package substrate supporting the semiconductor die, the package substrate including a first glass sheet having a first surface, a second surface opposite the first surface, and third surfaces extending between the first and second surfaces, a first via extending between the first surface of the first glass sheet and the second surface of the first glass sheet, and dielectric material disposed on the first surface of the first glass sheet and on a third surface of the first glass sheet that extends between the first and second surfaces.

Example 19 includes the package of example 18, further including a second glass sheet positioned on the dielectric material such that a fourth surface of the second glass sheet faces the first surface of the first glass sheet, a second via extending between the fourth surface of the second glass sheet and a fifth surface of the first glass sheet that is opposite the fourth surface, and buffer material disposed on a sixth surface of the second glass sheet that extends between the fourth and fifth surfaces of the second glass sheet.

Example 20 includes the package of example 19, wherein the dielectric material on the third surfaces of the first glass sheet and the buffer material on the sixth surface of the second glass sheet define an exterior surface of the integrated circuit package.

Example 21 includes the package of example 19 or example 20, wherein the dielectric material includes at least one of epoxy or a phenolic hardener.

Example 22 the package of any one of examples 19-21, wherein the dielectric material includes glass.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A device comprising:
a first glass layer including a first surface, a second surface opposite the first surface, and first lateral surfaces extending between the first and second surfaces, the first glass layer having a first via extending between the first surface and the second surface; and
a dielectric material in contact with the first surface of the first glass layer and in contact with the first lateral surfaces of the first glass layer.

2. The device of claim 1, further including a second glass layer having a third surface and a fourth surface opposite the third surface, the second glass layer having a second via extending between the third and fourth surfaces, the third surface positioned adjacent the first surface of the first glass layer, the first via aligned relative to the second via.

3. The device of claim 2, wherein the first via has a first diameter and the second via has a second diameter, the first diameter being smaller than the second diameter.

4. The device of claim 2, further including a third via in the dielectric material such that the third via is aligned relative to the first and second via.

5. The device of claim 4, wherein the first via has a first diameter, the second via has a second diameter that is substantially similar to the first diameter, and the third via has a third diameter that is larger than the first diameter and larger than the second diameter.

6. The device of claim 2, further including a bond material positioned between the first glass layer and the second glass layer.

7. The device of claim 2, further including a buffer material in contact with the fourth surface of the second glass layer and in contact with second lateral surfaces of the second glass layer that extend between the third and fourth surfaces of the second glass layer.

8. The device of claim 7, wherein outer lateral surfaces of the buffer material are substantially flush with outer lateral surfaces of the dielectric material.

9. The device of claim 7, wherein a portion of the buffer material is in contact with a portion of the dielectric material to define an interface that is substantially parallel relative to the first surface of the first glass layer.

10. The device of claim 1, wherein the first via includes an air gap positioned adjacent a wall of the first via.

11. The device of claim 1, wherein the dielectric material substantially encloses the first lateral surfaces of the first glass layer.

12. The device of claim 1, wherein the first glass layer includes a glass protrusion extending from a first one of the first lateral surfaces, the dielectric material is in contact with a fifth surface of the glass protrusion that is perpendicular relative to the first and second surfaces of the first glass layer.

13. An apparatus comprising:
a first glass substrate having a first via extending therethrough; and
first dielectric material positioned on a first edge of the first glass substrate, the first edge extending in a direction perpendicular to a first surface of the first glass substrate.

14. The apparatus of claim 13, wherein the first edge is defined by a perimeter of the first glass substrate.

15. The apparatus of claim 13, further including:
a second glass substrate having a second via extending therethrough; and
second dielectric material positioned between the first glass substrate and the second glass substrate, the second dielectric material having a third via extending therethrough, the third via extending between the first via and the second via to electrically couple the first glass substrate and the second glass substrate.

16. The apparatus of claim 15, further including a buffer layer positioned on a second edge of the second glass substrate, the second edge of the second glass substrate being substantially parallel to the first edge of the first glass substrate.

17. The apparatus of claim 16, wherein a thickness of the first dielectric material is substantially similar to a thickness of the buffer layer.

18. A package comprising:
a semiconductor die; and
a package substrate supporting the semiconductor die, the package substrate including:
a first glass sheet having a first surface, a second surface opposite the first surface, and third surfaces extending between the first and second surfaces;
a first via extending between the first surface of the first glass sheet and the second surface of the first glass sheet; and
dielectric material disposed on the first surface of the first glass sheet and on a third surface of the first glass sheet that extends between the first and second surfaces.

19. The package of claim 18, further including:
a second glass sheet positioned on the dielectric material such that a fourth surface of the second glass sheet faces the first surface of the first glass sheet;
a second via extending between the fourth surface of the second glass sheet and a fifth surface of the first glass sheet that is opposite the fourth surface; and
buffer material disposed on a sixth surface of the second glass sheet that extends between the fourth and fifth surfaces of the second glass sheet.

20. The package of claim 19, wherein the dielectric material on the third surfaces of the first glass sheet and the buffer material on the sixth surface of the second glass sheet define an exterior surface of the package.
